(19) United States
(12) Patent Application Publication
(10) Pub. No.: US 2025/0203891 A1
(43) Pub. Date: Jun. 19, 2025

(54) CAPACITOR

(71) Applicant: Murata Manufacturing Co., Ltd., Nagaokakyo-shi (JP)

(72) Inventors: Sota YANAI, Nagaokakyo-shi (JP); Yasuhiro SHIMIZU, Nagaokakyo-shi (JP); Masaki NAGATA, Nagaokakyo-shi (JP); Nobuaki SHIRAI, Nagaokakyo-shi (JP)

(21) Appl. No.: 19/068,205

(22) Filed: Mar. 3, 2025

Related U.S. Application Data
(63) Continuation of application No. PCT/JP2023/026070, filed on Jul. 14, 2023.

(30) Foreign Application Priority Data
Nov. 1, 2022 (JP) 2022-175699

(51) Int. Cl. H10D 1/68

(52) U.S. Cl. CPC H10D 1/692

(57) ABSTRACT

A capacitor that includes: a substrate with conductivity; a plurality of fiber-shaped conductive members on the substrate and electrically connected to the substrate; a dielectric layer covering a surface of the plurality of fiber-shaped conductive members; and a conductor layer covering a surface of the dielectric layer, wherein the plurality of fiber-shaped conductive members, the dielectric layer, the conductor layer, and a space among the plurality of fiber-shaped conductive members covered with the dielectric layer and the conductor layer constitute a composite bulk member, and in a section in the thickness direction of the substrate, the composite bulk member has a width W₁ on a side thereof opposite to the substrate and a width W₂ on a side thereof proximal to the substrate, with an in-plane direction of the substrate as a width direction, and the width W₁ is smaller than the width W₂.

### CROSS REFERENCE TO RELATED APPLICATIONS

The present application is a continuation of International application No. PCT/JP2023/026070, filed Jul. 14, 2023, which claims priority to Japanese Patent Application No. 2022-175699, filed Nov. 1, 2022, the entire contents of each of which are incorporated herein by reference.

### TECHNICAL FIELD

The present disclosure relates to a capacitor and, more particularly, to a capacitor that has a conductor-dielectric-conductor structure.

### BACKGROUND ART

Conventionally, it is known that capacitors can be manufactured with the use of a fiber-shaped members. For example, Patent Document 1 describes a method of forming a capacitor that has a metal-insulator-metal (MIM) structure by forming fiber-shaped members on a substrate (base surface) and sequentially forming, on the surface thereof, a lower plate (metal), an insulating layer, and an upper plate (metal).
Patent Document 1: Japanese Patent Application Laid-Open (Translation of PCT Application) No. 2010-506391
Non-Patent Document 1: Michael F L De Volder, Sei Jin Park, Sameh H Tawfick, Daniel O Vidaud and A John Hart, “Fabrication and electrical integration of robust carbon nanotube micropillars by self-directed elastocapillary densification”, Journal of Micromechanics and Microengineering, 2011.

### SUMMARY OF THE DISCLOSURE

When the fiber-shaped members have conductivity, a capacitor that has a conductor-dielectric-conductor structure can be formed by forming, on the surfaces of the fiber-shaped conductive members, a dielectric layer and further forming a conductor layer.

As a plurality of fiber-shaped conductive members, for example, vertically aligned carbon nanotubes (hereinafter, referred to also as “VACNTs”) can be used. VACNTs can be obtained by high-density growth thereof on a substrate with a catalyst attached thereto. A plurality of VACNTs constitute a forest. In a capacitor, the VACNTs are covered with a dielectric layer and a conductor layer.

The forest (composite bulk member) covered with the dielectric layer and the conductor layer has contact with the substrate mainly at the dielectric layer. The substrate and the dielectric layer has a difference therebetween in thermal expansion coefficient. For that reason, when the capacitor or a precursor therefor is heated, peeling may be caused between the substrate and the composite bulk member due to the difference in thermal expansion coefficient.

An object of the present disclosure is to provide a capacitor, which is high in joining strength between a substrate and a composite bulk member.

According to a gist of the present disclosure, provided is a capacitor including: a substrate with conductivity; a plurality of fiber-shaped conductive members on the substrate and electrically connected to the substrate; a dielectric layer covering a surface of each of the plurality of fiber-shaped conductive members; and a conductor layer covering a surface of the dielectric layer, wherein the plurality of fiber-shaped conductive members, the dielectric layer, the conductor layer, and a space among the plurality of fiber-shaped conductive members covered with the dielectric layer and the conductor layer constitute a composite bulk member, and in a section in the thickness direction of the substrate, the composite bulk member has a width W₁ on a first side opposite to the substrate and a width W₂ on a second side proximal to the substrate, with an in-plane direction of the substrate as a width direction, and the width W₁ is smaller than the width W₂.

According to the present disclosure, a capacitor is provided, which is high in joining strength between a substrate and a composite bulk member.

### BRIEF EXPLANATION OF THE DRAWINGS

FIG. 1 is a schematic sectional view of a capacitor according to Embodiment 1 of the present disclosure.

FIG. 2 is an enlarged view of a part A in FIG. 1.

FIG. 3A is an enlarged view of a part B in FIG. 1.

FIG. 3B is a sectional view of the part B in FIG. 1 in an in-plane direction of a substrate.

FIG. 4 is a schematic sectional view of a capacitor according to Embodiment 2 of the present disclosure.

FIG. 5A is an enlarged view of a part D in FIG. 4.

FIG. 5B is a sectional view of the part D in FIG. 4 in an in-plane direction of a substrate.

FIG. 6 is an optical microscope photograph showing a part of a section of a composite bulk member obtained according to Manufacturing Example 1 in the thickness direction of a substrate.

FIG. 7A is a schematic sectional view of a conventional capacitor.

FIG. 7B is a schematic sectional view of the conventional capacitor, showing a composite bulk member peeled off.

FIG. 8A is an SEM image obtained by photographing a part of an outer peripheral region in the polished XZ section of the composite bulk member obtained according to Manufacturing Example 1.

FIG. 8B is an SEM image obtained by photographing a part of a central region in the polished XZ section of the composite bulk member obtained according to Manufacturing Example 1.

FIG. 9A is an SEM image obtained by photographing a part of the outer peripheral region in a polished XY section of the composite bulk member obtained according to Manufacturing Example 1.

FIG. 9B is an SEM image obtained by photographing a part of the central region in the polished XY section of the composite bulk member obtained according to Manufacturing Example 1.

### DESCRIPTION OF THE PREFERRED EMBODIMENTS

Hereinafter, a capacitor according to an aspect of the present disclosure will be described in detail with reference to illustrated embodiments. It is to be noted that the drawings include some schematic drawings, and do not reflect actual dimensions or ratios in some cases. The present disclosure is not limited to these embodiments.

### Embodiment 1

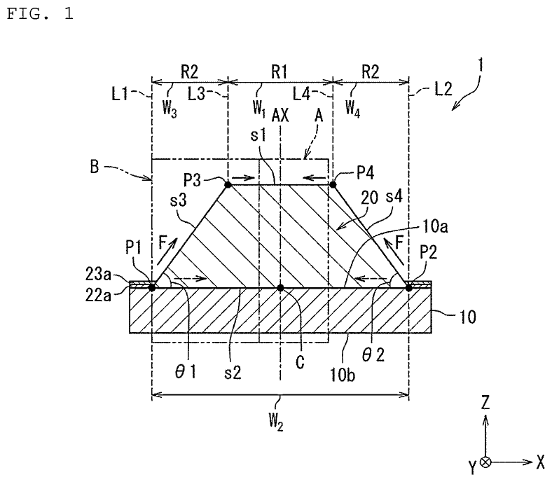

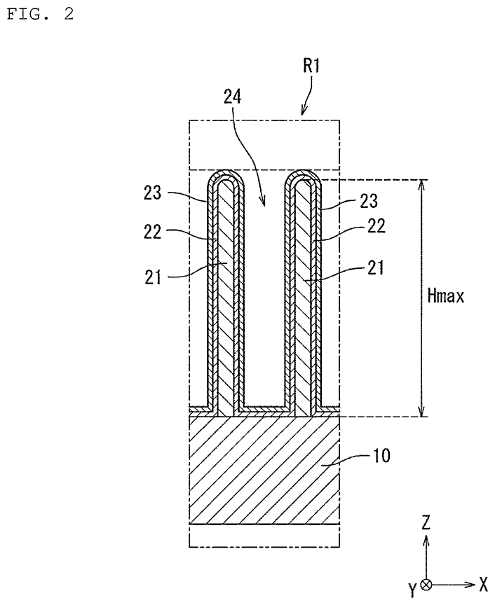

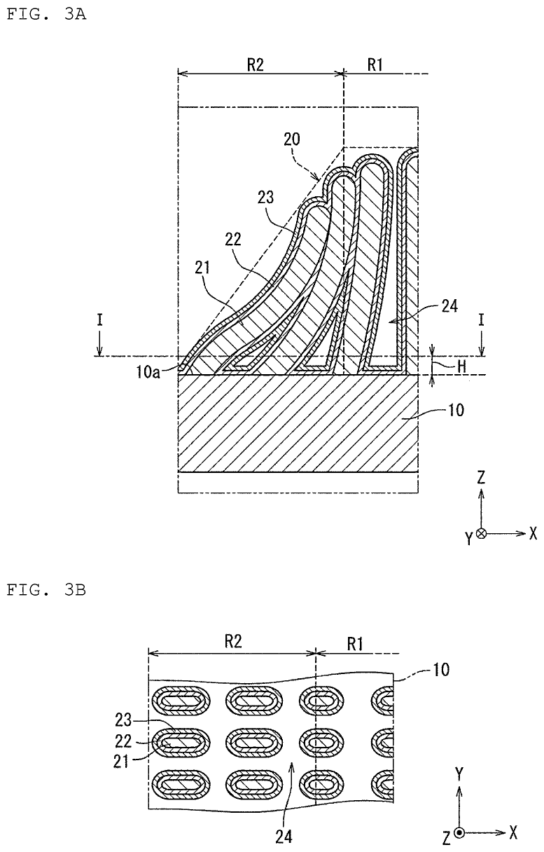

FIG. 1 is a schematic sectional view of a capacitor according to Embodiment 1. FIG. 1 shows a section in the thickness direction of a substrate 10. FIG. 1 shows therein, for the sake of convenience, the substrate 10 and the outer shape of a composite bulk member 20, while fiber-shaped conductive members 21, a dielectric layer 22, and a conductor layer 23 are omitted. FIG. 2 is an enlarged view of a part A in FIG. 1. FIG. 2 schematically shows therein the fiber-shaped conductive members 21 sequentially covered with the dielectric layer 22 and the conductor layer 23. FIG. 3A is an enlarged view of a part B in FIG. 1. FIG. 3A schematically shows therein the fiber-shaped conductive members 21 sequentially covered with the dielectric layer 22 and the conductor layer 23. FIG. 3B is a sectional view of the part B in FIG. 1 in an in-plane direction of the substrate. FIG. 3B corresponds to the I-I section of FIG. 3A. For the sake of convenience, FIGS. 3A and 3B show only parts of the substrate 10, fiber-shaped conductive members 21, dielectric layer 22, and conductor layer 23.

In the drawings, the thickness direction of the substrate 10 is defined as a Z direction. The straight line including the center C of the substrate 10 when the capacitor 1 is viewed from the Z direction and extending along the Z direction is defined as a central axis AX. The center C of the substrate 10 is typically coaxial with the center of the capacitor 1. A direction that is orthogonal to the Z direction of a section obtained by cutting the capacitor 1 along a plane including the central axis AX and extending in the Z direction is defined as an X direction (referred to also as a width direction in an XZ section). The X direction is an example of a direction in parallel with the in-plane direction of the substrate 10. A direction that is orthogonal to the Z direction and the X direction is defined as a Y direction (referred to also as a width direction in a YZ section).

The plane obtained by cutting the capacitor 1 along a plane that is formed by a straight line extending in the X direction and a straight line extending in the Z direction and includes the central axis AX is defined as an XZ section. The XZ section is an example of a section in the thickness direction of the substrate 10. The plane obtained by cutting the capacitor 1 along a plane that is formed by a straight line extending in the Y direction and a straight line extending in the Z direction and includes the central axis AX is defined as a YZ section. The YZ section is another example of the section in the thickness direction of the substrate 10. The plane obtained by cutting the capacitor 1 along a plane that is formed by a straight line extending in the X direction and a straight line extending in the Y direction is defined as an XY section. The XY section is a section in parallel with the in-plane direction of the substrate 10. The center C of the substrate 10 is the center of the smallest circle enclosing the substrate 10 when the capacitor 1 is viewed from the Z direction.

In the Z direction, a direction from the substrate 10 toward the composite bulk member 20 may be referred to as an upward direction. The upper side of an element refers to the side of the element in the upward direction. In the Z direction, a direction from the composite bulk member 20 toward the substrate 10 may be referred to as an downward direction. The lower side of an element refers to the side of the element in the downward direction. In the XZ section, the X direction may be referred to as a left-right direction. The right side of an element refers to the side of the element in the rightward direction. The left side of an element refers to the side of the element in the leftward direction.

### (Configuration)

The capacitor 1 includes: a substrate 10 with conductivity; a plurality of fiber-shaped conductive members 21 disposed on the substrate 10 and electrically connected to the substrate 10; a dielectric layer 22 that covers the surface of the fiber-shaped conductive members 21; and a conductor layer 23 that covers the surface of the dielectric layer 22. The capacitor 1 may have a conductive member (not shown) in contact with the conductor layer 23. The plurality of fiber-shaped conductive members 21, the dielectric layer 22, the conductor layer 23, and the space 24 formed among the plurality of fiber-shaped conductive members covered with the dielectric layer 22 and the conductor layer 23 constitute the composite bulk member 20. The space 24 may be filled with a filling material such as resin. The conductive member will be described later.

In the capacitor 1, the term “on the substrate 10” can be rephrased as a face (surface 10a to be described later) that is an outer surface of the substrate 10, in parallel with a plane (XY plane) formed by a straight line extending in the X direction and a straight line extending in the Y direction.

In addition to the surface (provided that the regions directly joined to the substrate 10 are excluded) of the fiber-shaped conductive members 21, the dielectric layer 22 may cover a part of the surface 10a of the substrate 10 without any fiber-shaped conductive member 21 disposed thereon among the plurality of fiber-shaped conductive members 21. The dielectric layer 22 may be formed to be continuous with a dielectric part 22a that covers a part of the surface 10a of the substrate 10 without any fiber-shaped conductive member 21 disposed thereon, outside the plurality of fiber-shaped conductive members 21. The composite bulk member 20 includes, however, no dielectric part 22a.

The conductor layer 23 may cover the dielectric layer 22 among the plurality of fiber-shaped conductive members 21, in addition to the dielectric layer 22 covering the surface of the fiber-shaped conductive members 21. A part of the conductor layer 23, covering the dielectric layer 22 among the plurality of fiber-shaped conductive members 21, can be understood as defining the bottom of the space 24 (for example, the bottom of the trench). The conductor layer 23 may be formed to be continuous with a conductor part 23a that covers the dielectric part 22a outside the plurality of fiber-shaped conductive members 21. The composite bulk member 20 includes, however, no conductor part 23a.

The fiber-shaped conductive members 21 are directly joined to the substrate 10. More specifically, the fiber-shaped conductive members 21 and the substrate 10 are joined in direct contact with each other. The fiber-shaped conductive members 21 are directly synthesized on the surface 10a of the substrate 10.

The plurality of fiber-shaped conductive members 21 have conductivity, (which are typically conductors), which can be kept at the same potential or voltage as each other with the members electrically connected to the substrate 10. Accordingly, a conductor-dielectric-conductor structure is formed by the fiber-shaped conductive members 21, the dielectric layer 22, and the conductor layer 23. Such a conductor-dielectric-conductor structure can be understood as corresponding to a so-called MIM structure (metal-insulator-metal structure). The capacitor 1 that has such a structure can achieve a high capacitance density from the large specific surface area of the fiber-shaped conductive members 21.

### (Composite Bulk Member)

The composite bulk member 20 includes the plurality of fiber-shaped conductive members 21 (hereinafter, referred to as conductive fibers 21), the dielectric layer 22, the conductor layer 23, and the space 24 formed among the plurality of conductive fibers 21 (hereinafter, simply referred to also as covered conductive fibers 21) covered with the dielectric layer 22 and the conductor layer 23.

### Method for Determining Composite Bulk Member 20

The composite bulk member 20 can be determined from a section (for example, a XZ section) in the thickness direction of the capacitor 1. The composite bulk member 20 is, because including no dielectric part 22a or conductor part 23a as mentioned above, determined to exclude the parts. Hereinafter, the determination will be described mainly with reference to an XZ section as the section in the thickness direction.

First, the space 24 formed among the covered conductive fibers 21 is embedded with any appropriate filling resin. Next, the center C of the substrate 10 is determined with the capacitor 1 viewed from the Z direction.

The section (XZ section herein) including the center C in the thickness direction of the capacitor 1 is exposed by polishing. The obtained XZ section (No. 1) is observed with a scanning electron microscope (SEM). The substrate 10; and a first member (not shown) including the conductive fibers 21, the dielectric layer 22 (and the dielectric part 22a, if present, the same shall apply hereinafter) the conductor layer 23 (and the conductor part 23a, if present, the same shall apply hereinafter), and the filling resin (corresponding to the space 24 mentioned above), disposed on the front surface 10a of the substrate 10, can be confirmed in the SEM image of the XZ section (No. 1). Furthermore, a conductive member can be present.

The SEM image is subjected to image processing to identify and distinguish from each other the conductive fibers 21, the dielectric layer 22, the conductor layer 23, the filling resin (space 24), and furthermore, the conductive member in the first member. Elemental analysis by energy dispersive X-ray spectroscopy (EDX) may be used in combination for the identification.

In the XZ section, the composite bulk member 20 is substantially quadrangular. The conductive fibers 21 in the vicinity of the four corners of the composite bulk member 20 are each identified in the SEM image. In this identification, a part including each of the corners in the SEM image may be enlarged so as to obtain an observation field of view of about 1 μm×1 μm.

The leftmost conductive fiber 21 located on the leftmost side of the first member closest to the substrate 10 is identified in the SEM image. Then, the dielectric layer 22 and conductor layer 23 covering the leftmost conductive fiber 21 are determined. These layers can be present to be respectively continuous with the dielectric part 22a and the conductor part 23a. The thickness of the dielectric layer 22 (and the dielectric part 22a, the same shall apply hereinafter) covering the conductive fiber 21 is substantially uniform in terms of manufacturing method. Thus, the outer edge of the dielectric layer 22 covering the leftmost conductive fiber 21 can be determined in consideration of the thickness of the dielectric layer 22 covering the other conductive fibers 21. The thickness of the conductor layer 23 (and the conductor part 23a, the same shall apply hereinafter) covering the conductive fiber 21 with the dielectric layer 22 interposed therebetween is also substantially uniform in terms of manufacturing method. Thus, the outer edge of the conductor layer 23 covering the leftmost conductive fiber 21 can be determined in consideration of the thickness of the conductor layer 23 covering the other conductive fibers 21.

Drawn is a first straight line L1 in contact with the determined outer edge of the conductor layer 23 and in parallel with the central axis AX. The tangent point between the first straight line L1 and the conductor layer 23 is a left bottom P1 of the composite bulk member 20. The left bottom P1 is typically on the surface 10a of the substrate 10. The first straight line L1 is intended to define the boundary (virtual boundary, the same shall apply hereinafter) between the dielectric layer 22 and the dielectric part 22a and the boundary between the conductor layer 23 and the conductor part 23a. With respect to the first straight line L1, the dielectric layer 22 is located on the right side, and the dielectric part 22a is located on the left side. With respect to the first straight line L1, the conductor layer 23 is located on the right side, and the conductor part 23a is located on the left side. The dielectric part 22a and conductor part 23a described above are not included in the composite bulk member 20.

Similarly, the conductive fiber 21 located on the rightmost side of the first member closest to the substrate 10 is identified, and the dielectric layer 22 and conductor layer 23 covering the rightmost conductive fiber 21 are determined. Drawn is a second straight line L2 in contact with the outer edge of the conductor layer 23 and in parallel with the central axis AX. The tangent point between the second straight line L2 and the conductor layer 23 is a right bottom P2 of the composite bulk member 20. The right bottom P2 is typically on the surface 10a of the substrate 10. The second straight line L2 is intended to define the boundary between the dielectric layer 22 and the dielectric part 22a and the boundary between the conductor layer 23 and the conductor part 23a. With respect to the second straight line L2, the dielectric layer 22 is located on the left side, and the dielectric part 22a is located on the right side. With respect to the second straight line L2, the conductor layer 23 is located on the left side, and the conductor part 23a is located on the right side. The dielectric part 22a and conductor part 23a described above are not included in the composite bulk member 20.

Similarly, the conductive fibers 21 located on the opposite side of the first member from the substrate 10 and located on the leftmost side and the rightmost side are identified, and the dielectric layers 22 and conductor layers 23 covering the conductive fibers 21 are determined. Drawn is a third straight line L3 in contact with the outer edge of the conductor layer 23 covering the conductive fiber 21 at the left apex and in parallel with the central axis AX. The tangent point between the third straight line L3 and the conductor layer 23 is a left apex P3 of the composite bulk member 20. Drawn is a fourth straight line L4 in contact with the outer edge of the conductor layer 23 covering the conductive fiber 21 at the right apex and in parallel with the central axis AX. The tangent point between the fourth straight line L4 and the conductor layer 23 is a right apex P4 of the composite bulk member 20.

Also in the case of the conductor layer 23 in contact with the conductive member, the outer edge of the conductor layer 23 can be similarly determined in consideration of the thickness of the conductor layer 23 covering the other conductive fibers 21. The conductive member is not included in the composite bulk member 20.

The composite bulk member 20 includes the plurality of conductive fibers 21, the dielectric layer 22, the conductor layer 23, and the space 24 that are present in the region sandwiched between the first straight line L1 and the second straight line L2. The quadrangle obtained by connecting the left bottom P1, the right bottom P2, the right apex P4, and the left apex P3 represents the outer shape of the composite bulk member 20.

<Widths W₁ and W₂>

In the section in the thickness direction, the composite bulk member 20 according to the present embodiment is a trapezoid where the upper side (upper side s1) is shorter than the lower side (lower side s2). More specifically, the composite bulk member 20 has a width W₁ on the side opposite to the substrate 10 and a width W₂ on the side closer to the substrate 10 in the XZ section, and the width W₁ is smaller than the width W₂ (W₁<W₂). Furthermore, the angle θ1 of the interior angle formed by the lower side s2 and the left side (left side s3) and the angle θ2 of the interior angle formed by the lower side s2 and the right side (right side s4) are both less than 90 degrees in the composite bulk member 20 in the XZ section.

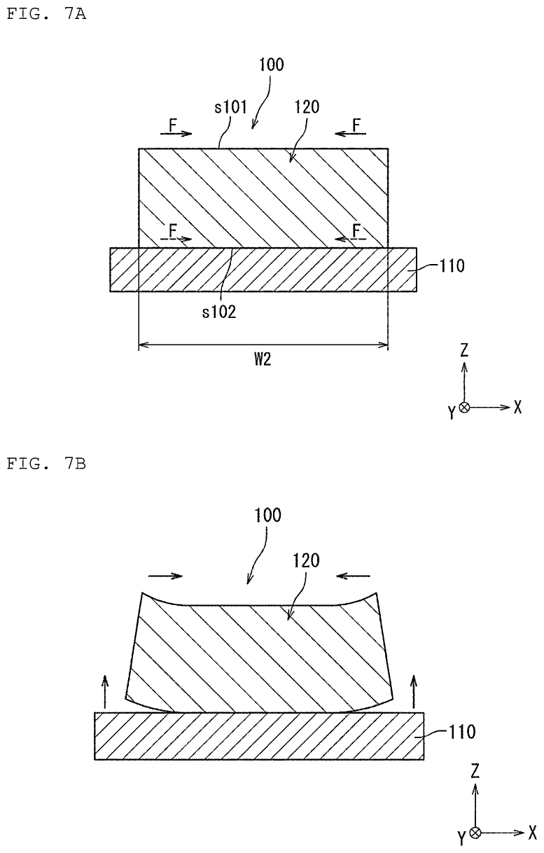

As shown in FIG. 7A, an XZ section of a composite bulk member 120 in a conventional capacitor 100 is typically a rectangle where an upper side s101 and a lower side s102 have substantially the same length (W₂) and the four corners each have substantially 90 degrees. When the capacitor 100 or a precursor therefor is heated and cooled, the composite bulk member 120 tends to shrink significantly. Since the lower side s102 is, however, joined to a substrate 110, the lower side s102 is not capable of shrinking in the X direction, and thus, shrinkage stress F acts in the Z direction. In addition, the upper side s101 is capable of shrinking without limitation, the shrinkage is likely to be increased. When the shrinkage of the upper side s101 is increased, the ends of the lower side s102 are further pulled in the Z direction. As a result, as shown in FIG. 7B, the composite bulk member 120 is peeled off from the substrate 110.

In the present embodiment, because the upper side s1 is shorter than the lower side s2 (W₁<W₂), the shrinkage of the upper side s1 is smaller than the shrinkage of the lower side s2. Furthermore, because the left side s3 and right side s4 of the composite bulk member 20 are inclined with respect to the Z direction, the shrinkage stress F applied to the lower side s2 is dispersed in the Z direction and the X direction. Thus, the stress that tends to pull the ends of the lower side s2 in the Z direction is lower than that in the conventional capacitor. Accordingly, the composite bulk member 20 is kept from being peeled from the substrate 10.

As described above, according to the present disclosure, the strength of the composite bulk member 20 is increased while keeping the performance of the capacitor 1 from being degraded due to the unnecessarily thickened dielectric layer 22 for the whole composite bulk member 20, thereby allowing the composite bulk member 20 to be kept from being peeling.

The precursor for the capacitor 1 refers to, for example, a precursor including the substrate 10, the plurality of conductive fibers 21, and the dielectric layer 22 before the formation of the conductor layer 23.

The capacitor 1 or a precursor therefore may be heated and cooled, for example, in a drying step, a firing step, and a film forming step for the dielectric layer 22, in a process for manufacturing the capacitor 1, and in the use of the capacitor 1. Hereinafter, the stress applied in the X direction toward the center of the composite bulk member 20 is referred to as tensile stress.

The relationship of W₁<W₂ may be satisfied in one section in the thickness direction.

The relationship of W₁<W₂ may be satisfied in multiple different sections in the thickness direction. The relationship of W₁<W₂ may be satisfied in three or more different sections in the thickness direction. The relationship of W₁<W₂ may be satisfied in any section in the thickness direction. In this case, the effect of relaxing the tensile stress can be further improved.

The multiple different sections in the thickness direction are XZ sections, and can be YZ sections. The multiple different sections in the thickness direction can be obtained by rotating a XZ section around the central axis AX by less than 360 degrees.

Method for Calculating Width W₁ and Width W₂

The width W₁ is a distance in the X direction between a straight line including one end of a side on the upper side (upper side) of the composite bulk member 20 and extending in the Z direction and a straight line including the other end and extending in the Z direction in the XZ section. The width W₂ is a distance in the X direction between a straight line including one end of a side on the lower side (lower side) of the composite bulk member 20 and extending in the Z direction and a straight line including the other end and extending in the Z direction in the XZ section.

Specifically, as shown in FIG. 1, the width W₁ is a distance in the X direction between the first straight line L1 and the second straight line L2. The width W₂ is a distance in the X direction between the third straight line L3 and the fourth straight line L4.

The width W₁ and the width W₂ in the multiple sections are calculated as follows. First, for the composite bulk member 20 with the XZ section (No. 1) exposed, another section (for example, a YZ section: No. 2) in the thickness direction is further exposed by polishing. The section (No. 2) represents a part (half) of a section of the composite bulk member 20 in the thickness direction. The obtained section (No. 2) is observed with an SEM to identify the bottoms P11 and P21 and apexes P31 and P41 of the halved composite bulk member 20 (the illustration of P11 to P41 is omitted). Next determined are: the distance W₂₁ in the X direction between a straight line including the left bottom P11 and extending in the Z direction and a straight line including the right bottom P21 and extending in the Z direction; and the distance W₁ in the X direction between a straight line including the left apex P31 and extending in the Z direction and a straight line including the right apex P41 and extending in the Z direction.

While the section (No. 2) represents a half of the section of the composite bulk member 20 in the thickness direction as mentioned above, the other half may be considered to have the same configuration as the section (No. 2). Thus, the width W₁ is obtained by doubling the distance W₁₁. Similarly, the width W₂ is obtained by doubling the distance W₂₁. Repeating such an operation and calculation for multiple sections in the thickness direction as necessary allows the width W₁ and the width W₂ in the multiple sections in the thickness direction to be each obtained. One width W₁ and one width We are each obtained for one section in the thickness direction. The relationship of W₁<W₂ may be satisfied in each of the multiple sections in the thickness direction.

The upper side s1 is a line segment formed by connecting the left apex P3 and the right apex P4. The lower side s2 is a line segment formed by connecting the left bottom P1 and the right bottom P2. The left side s3 is a line segment formed by connecting the left bottom P1 and the left apex P3. The right side s4 is a line segment formed by connecting the right bottom P2 and the right apex P4. The upper side s1, the lower side s2, the left side s3, and the right side s4 are outer edges of the composite bulk member 20. In the present embodiment, the outer shape of the composite bulk member 20 formed by connecting the four line segments is substantially trapezoidal.

### <Angles θ1 and θ2>

In one section in the thickness direction, the angle θ1 of the interior angle and the angle θ2 of the interior angle are both less than 90 degrees. θ1 is the angle of the interior angle formed by the lower side s2 and the left side s3. θ2 is the angle of the interior angle formed by the lower side s2 and the right side s4. The angles θ1 and θ2 are measured in the following manner with the use of the SEM image of the XZ section (No. 1) used to calculate the width W₁ and the width W₂. In the SEM image, the bottoms P1 and P2 and the apexes P3 and P4 are already determined. The left bottom P1 and the right bottom P2 are connected to obtain the lower side s2. The left bottom P1 and the left apex P3 are connected to obtain the left side s3. The right bottom P2 and the right apex P4 are connected to obtain the right side s4. The angle θ1 is determined by measuring the angle of the interior angle formed by the obtained lower side s2 and left side s3. The angle θ2 is determined by measuring the angle of the interior angle formed by the lower side s2 and the right side s4.

The relationship of θ1 and θ2<90 degrees may be satisfied in multiple different sections in the thickness direction. The relationship of θ1 and θ2<90 degrees may be satisfied in three or more different sections in the thickness direction. The relationship of θ1 and θ2<90 degrees may be satisfied in any section in the thickness direction. The angles θ1 and θ2 in multiple sections in the thickness direction can be measured and assumed with the use of the above-mentioned YZ section (No. 2) or the like.

### <Central Region R1 and Outer Peripheral Region R2>

The composite bulk member 20 has, in the section in the thickness direction, a central region R1 corresponding to the width W₁ and outer peripheral regions R2 on one side and the other side sandwiching the central region R1 therebetween. The “central region R1 corresponding to the width W₁” is a region sandwiched by the straight line including one end of the side on the upper side (upper side) of the composite bulk member 20 and extending in the Z direction and the straight line including the other end (the distance in the X direction between the two ends is the width W₁) and extending in the Z direction in the XZ section.

Specifically, as shown in FIG. 1, the central region R1 is the region sandwiched by the third straight line L3 and fourth straight line L4 of the composite bulk member 20. The outer peripheral regions R2 corresponding to the other region of the composite bulk member 20 excluding the central region R1 are disposed at two sites of both ends in the X direction with the central region R1 sandwiched therebetween. The outer peripheral regions R2 on one side and the other side face each other with the central region R1 interposed therebetween.

In the central region R1, the conductive fiber 21 has a maximum height Hₘₐₓ. The maximum height Hₘₐₓ, the width W₁, and the width W₂ may satisfy the following relational expression:

$${W}_{2} - {W}_{1} \geq 1.6 \times {H}_{max}$$

(W₂−W₁) represents the total width of the outer peripheral regions R2 on both the sides. The inclination of the left side s3 and/or the right side s4 with respect to the central axis AX can be considered larger as (W₂−W₁) is larger. From the viewpoint of relaxing the tensile stress, (W₂−W₁) is desirably larger.

In particular, when (W₂−W₁) is 1.6 times or more as large as the maximum height Hₘₐₓ of the conductive fiber 21, the effect of relaxing tensile stress is further produced. (W₂−W₁) may be 2.0 times or more as large as the maximum height Hₘₐₓ of the conductive fiber 21.

In contrast, considering the outer diameter of the capacitor 1, (W₂−W₁) is desirably not excessively large. Furthermore, from the viewpoint of capacitance, the maximum height Hₘₐₓ of the conductive fiber 21 is desirably secured to some extent. Thus, (W₂−W₁) may be 50 times or less, and may be 10 times or less as large as the maximum height Hₘₐₓ of the conductive fiber 21.

The relationship of W₂−W₁≥1.6×Hₘₐₓ may be satisfied in one section in the thickness direction. The above-mentioned relationship may be satisfied in multiple different sections in the thickness direction, may be satisfied in three or more different sections in the thickness direction, and may be satisfied in any section in the thickness direction. In this case, the effect of relaxing the tensile stress can be further improved.

As the area of contact between the composite bulk member 20 (in particular, the dielectric layer 22) and the substrate 10 is increased, the tensile stress applied to the composite bulk member 20 is also increased, and then more likely to be peeled off. According to the present disclosure, however, also when the area of contact between the composite bulk member 20 with the substrate 10 is large, for example, also when the length (width W₂) of the lower side is larger than the maximum height Hₘₐₓ of the conductive fiber 21 (W₂>Hₘₐₓ), the composite bulk member 20 can be kept from being peeled off.

The width W₂ may be four times or more, and may be 10 times or more as large as the maximum height Hₘₐₓ. The width W₂ may be 200,000 times or less, 100,000 times or less, or 1,000 times or less as large as the maximum height Hₘₐₓ. If the width W₂ is smaller than four times the maximum height Hₘₐₓ, the volume of the composite bulk member 20 will be excessively decreased, thus also decreasing the volume capacitance density of the capacitor 1.

### Method for Determining Maximum Height Hₘₐₓ

The maximum height Hₘₐₓ is determined from the SEM image of the XZ section (No. 1) mentioned above. The end of the conductive fiber 21 farthest from the surface 10a of the substrate 10 in the Z direction is identified, and the distance in the Z direction between the end and the surface 10a is the maximum height Hₘₐₓ.

<Widths W₃ and W₄>

From the viewpoint of relaxing the tensile stress, the angles θ1 and 02 are desirably small, that is, the inclinations of the left side s3 and right side s4 with respect to the central axis AX are desirably both large. The width W₃ of the composite bulk member 20 in the outer peripheral region R2 on one side and the width W₄ of the composite bulk member 20 in the outer peripheral region R2 on the other side are increased as the left side s3 and the right side s4 are inclined. The width W₃ and the width W₄ may satisfy, for example, the following relational expression:

$${W}_{3} \geq 0.8 \times {H}_{max} and {W}_{4} \geq 0.8 \times {H}_{max}$$

The width W₃ is the length of the composite bulk member 20 in the X direction in the left outer peripheral region R2. The width W₄ is the length of the composite bulk member 20 in the X direction in the right outer peripheral region R2.

Both W₃ and W₄ may be 1.0 times or more as large as the maximum height Hₘₐₓ of the conductive fiber 21. From the viewpoint of the volume capacitance density of the capacitor 1, both W₃ and W₄ may be 1,000 times or less, and may be 50 times or less as large as the maximum height Hₘₐₓ of the conductive fiber 21. W₃ may be the same as or different from W 4.

The above-mentioned relationship between W₃ and W₄ and the maximum height Hₘₐₓ may be satisfied in one section in the thickness direction. The above-mentioned relationship may be satisfied in multiple different sections in the thickness direction, may be satisfied in three or more different sections in the thickness direction, and may be satisfied in any section in the thickness direction.

Method for Calculating Width W₃ and Width W₄

The width W₃ and the width We are determined with the use of the SEM image of the XZ section (No. 1) mentioned above. The width W₃ is the distance in the X direction between the first straight line L1 and the third straight line L3. The width W₄ is the distance in the X direction between the second straight line L2 and the fourth straight line L4.

In the present embodiment, as shown in FIG. 3A, the conductive fibers 21 are inclined with respect to the Z direction or bent in the X direction in the outer peripheral region R2. Thus, in the outer peripheral region R2 (typically, the upper side thereof), the at least two conductive fibers 21 can be brought into contact with each other, with the dielectric layer 22 interposed therebetween or without the dielectric layer 22 interposed therebetween.

In the present embodiment, when the conductive fibers 21 have high strength (specifically, when the conductive fibers 21 have higher strength than the dielectric layer 22), the plurality of conductive fibers 21 can support each other in the outer peripheral regions R2 of the composite bulk member 20, and the composite bulk member 20 is less likely to be deformed by external forces. More specifically, the lower side s2 is further less likely to shrink in the Z direction, thereby further keeping the composite bulk member 20 from being peeled from the substrate 10. In addition, the conductive fibers 21 can function as a core material, and thus, cracks are kept from being generated in the composite bulk member 20 due to tensile stress.

The strength of the conductive fiber 21 is, for example, 5 MPa/(nm)² to 150 Gpa/(nm)². Thus, the conductive fibers 21 can be expected to function as a core material of the composite bulk member 20. The strength of the conductive fiber 21 may be 10 MPa/(nm)² or more, and may be 10 Gpa/(nm)² or more. The strength of the conductive fiber 21 may be 100 Gpa/(nm)² or less.

Examples of the conductive fiber 21 with the strength of 5 MPa/(nm)² to 150 Gpa/(nm) 2 include at least one selected from the group consisting of carbon nanotubes, metal nanowires, and conductive polymer wires.

<Area Occupancy Proportions S₁₁ and S₂₁>

As mentioned above, the conductive fibers 21 according to the present embodiment are inclined with respect to the Z direction or bent in the X direction in the outer peripheral region R2 of the XZ section. Thus, the space 24 present in the outer peripheral region R2 is smaller than the space 24 present in the central region R1. More specifically, the outer peripheral region R2 includes a part where the total area occupancy proportion S₂₁ of the conductive fibers 21 and dielectric layer 22 is higher than the total area occupancy proportion S₁₁ of the conductive fibers 21 and the dielectric layer 22 in the central region R1.

When the space 24 is small, the composite bulk member 20 is less likely to be deformed by external forces. Thus, the shrinkage of the lower side s2 in the Z direction is suppressed. In particular, the outer peripheral region R2, which is a start point of peeling, is kept from being deformed, the composite bulk member 20 is further kept from being peeled from the substrate 10.

The area occupancy proportion S₁₁ is the total area occupancy proportion of the conductive fibers 21 and dielectric layer 22 in any part of the central region R1 of any one section in the thickness direction. The area occupancy proportion S₂₁ is the total area occupancy proportion of the conductive fibers 21 and dielectric layer 22 in any part of the outer peripheral region R2 of the same section as mentioned above. If the area occupancy proportion S₂₁ is lower than the area occupancy proportion S₁₁ in a part of the outer peripheral region R2, the area occupancy proportion S₂₁ in the other part of the outer peripheral region R2 in the section has only to be higher than the area occupancy proportion S₁₁.

The above-mentioned relationship between the area occupancy proportions S₁₁ and S₂₁ has only to be satisfied in a part of any one section in the thickness direction. In any one section in the thickness direction, both the outer peripheral regions R2 on one side and the other side may include a part where the area occupancy proportion S₂₁ is higher than the area occupancy proportion S₁₁. Thus, the central region R1, which is relatively likely to be deformed, is reinforced from the left and the right, and the entire composite bulk member 20 is thus kept from shrinking in the width direction (for example, in the X direction). Accordingly, the composite bulk member 20 is made likely to be further kept from being peeled from the substrate 10.

In multiple different sections in the thickness direction, the outer peripheral regions R2 may include a part where the area occupancy proportion S₂₁ is higher than the area occupancy proportion S₁₁. Also in this case, the composite bulk member 20 is further kept from shrinking in the width direction. The fact that “ . . . include a part where . . . higher . . . in multiple sections in the thickness direction” means that the outer peripheral regions R2 in at least two different sections in the thickness direction include a part where the area occupancy proportion S₂₁ is higher than the area occupancy proportion S₁₁. The fact is not intended to mean that the outer peripheral regions R2 need to include a part where the area occupancy proportion S₂₁ is higher than the area occupancy proportion S₁₁ in all of the sections in the thickness direction.

In at least two different sections in the thickness direction, both the outer peripheral regions R2 on one side and the other side may include a part where the area occupancy proportion S₂₁ is higher than the area occupancy proportion S₁₁.

The fact that “the area occupancy proportion S₂₁ is higher” means that the difference between the area occupancy proportions S₁₁ and S₂₁ is 5% or more. More specifically, the fact refers to S₂₁/S₁₁≥1.05. S₂₁/S₁₁ may be 1.2 or more, 2 or more, or 5 or more.

The area occupancy proportion Si may be 0.1 or more, 0.15 or more, or 0.20 or more. The area occupancy proportion S₁₁ may be 0.5 or less, 0.4 or less, or 0.35 or less.

The area occupancy proportion S₂₁ may be 0.2 or more, 0.25 or more, or 0.30 or more. The area occupancy proportion S₂₁ may be 0.7 or less, 0.5 or less, or 0.45 or less.

Method for Calculating Area Occupancy Proportions S₁₁ and S₂₁

The area occupancy proportions S₁₁ and S₂₁ are calculated in the following manner with the use of the SEM image of the XZ section (No. 1) mentioned above. In the SEM image, the composite bulk member 20, the outer peripheral regions R2, and the central region R1 are already identified. In the composite bulk member 20, the conductive fiber 21, the dielectric layer 22, the conductor layer 23, and the filling resin (space 24) are distinguished.

The area of the conductive fibers 21 and dielectric layer 22 in the right outer peripheral region R2 is divided by the area of the outer peripheral region R2 (that is, the total of the parts including the conductive fibers 21, the dielectric layer 22, the conductor layer 23, and the filling resin). Thus, the area occupancy proportion S₂₁ of the right outer peripheral region R2 is calculated. Similarly, the area occupancy proportion S₂₁ of the left outer peripheral region R2 is calculated. Similarly, the area occupancy proportion S₁₁ of the central region R1 is calculated.

The observation field of view in this case may have a size such that only a part of the central region R1 can be observed. Similarly, the observation field of view may have a size such that only a part of the outer peripheral region R2 can be observed. The size of the observation field of view may be, for example, about 1 μm×1 μm. Thus, the conductive fibers 21, the dielectric layer 22, the conductor layer 23, and the filling resin are more easily distinguished.

The area occupancy proportions S₁₁ and S₂₁ in the multiple sections in the thickness direction may also be calculated with the use of the same idea as in the case of calculating the width W₁ and the width W₂ in the multiple sections in the thickness direction. More specifically, the part of the outer peripheral region R2 appearing in the section in the thickness direction and the other outer peripheral region R2 may be considered to have the same configuration, and the part of the central region R1 appearing in the section in the thickness direction and the other central region R1 may be considered to have the same configuration.

<Area Occupancy Proportions S₁₂ and S₂₂>

The outer peripheral region R2 includes a part where the total area occupancy proportion S₂₂ of the conductive fibers 21, dielectric layer 22, and the conductor layer 23 is higher than the total area occupancy proportion S₁₂ of the conductive fibers 21, the dielectric layer 22, and the conductor layer 23 in the central region R1. More specifically, S₂₂/S₁₂≥1.05 is satisfied. S₂₂/S₁₂ may be 1.2 or more, 2 or more, or 5 or more.

Also in the case mentioned above, the space 24 can be considered small, and thus, the composite bulk member 20 is less likely to be deformed by external forces.

Accordingly, the same effect is obtained as the case in which the outer peripheral region R2 includes a part where the area occupancy proportion S₂₁ is higher than the area occupancy proportion S₁₁ as mentioned above.

The matters described regarding the area occupancy proportion S₁₁ can be applied with the area occupancy proportion S₁₁ replaced with the area occupancy proportion S₁₂. The matters described regarding the area occupancy proportion S₂₁ can be applied with the area occupancy proportion S₂₁ replaced with the area occupancy proportion S₂₂.

Method for Calculating Area Occupancy Proportions S₁₂ and S₂₂

The area occupancy proportions S₁₂ and S₂₂ can be calculated in the same manner as the area occupancy proportions S₁₁ and S₂₁, except that the total area of the conductive fibers 21, the dielectric layer 22, and the conductor layer 23 is divided by the area of the central region R1 or the outer peripheral region R2.

<Area Occupancy Proportions S₁₃ and S₂₃>

In the section in the thickness direction, the conductive fiber 21 in the outer peripheral region R2 has a width direction component. Thus, as shown in FIG. 3B, the sectional area of the covered conductive fiber 21 in the outer peripheral region R2 is larger than that in the central region R1 in an XY section. More specifically, also in the XY section, as with the XZ section, the outer peripheral region R2 includes a part where the total area occupancy proportion S₂₃ of the conductive fibers 21, dielectric layer 22, and the conductor layer 23 is higher than the total area occupancy proportion S₁₃ of the conductive fibers 21, the dielectric layer 22, and the conductor layer 23 in the central region R1. More specifically, S₂₃/S₁₃≥1.05 is satisfied. S₂₃/S₁₃ may be 1.2 or more, 2 or more, or 5 or more.

The area occupancy proportion S₁₃ may be 0.08 or more, 0.10 or more, or 0.15 or more. The area occupancy proportion S₁₃ may be 0.50 or less, 0.40 or less, or 0.30 or less.

The area occupancy proportion S₂₃ may be 0.15 or more, 0.20 or more, or 0.25 or more. The area occupancy proportion S₂₃ may be 0.70 or less, 0.50 or less, or 0.40 or less.

FIG. 3B corresponds to the I-I section of FIG. 3A. The height H of the I-I section from the surface 10a of the substrate 10 is, for example, 20% or less of the maximum height Hₘₐₓ. As the I-I section is closer to the substrate 10, the sectional area of the covered conductive fiber 21 in the outer peripheral region R2 can be increased. One of the conductive fibers 21 may be disposed across the outer peripheral region R2 and the central region R1.

Method for Calculating Area Occupancy Proportions S₁₃ and S₂₃

The area occupancy proportions S₁₃ and S S₂₃ can be calculated with the use of the sample used for determining the central region R1 and the outer peripheral regions R2 and the section (XZ section) of the sample in the thickness direction. In the XZ section, the central region R1 and the outer peripheral regions R2 are already determined. First, the XY section of the sample at a first position where the height H from the surface 10a of the substrate 10 is 20% or less (typically, 10% or less) of the maximum height Hₘₐₓ is exposed by polishing. In this case, the XY section may be obtained by cutting or without cutting the dielectric part 22a or the conductor part 23a. While the obtained XY section shows a part (which can be half or less) of the XY section of the composite bulk member 20, the other part of the XY section may be also considered to have the same configuration as the part of the obtained XY section.

The outer shape of the composite bulk member 20 as viewed from the Z direction and the outer shape thereof in the XY section may be, for example, a circle, an ellipse, or a polygon.

Next, the central region R1 and the outer peripheral regions R2, determined with the use of the XZ section, are projected onto the obtained XY section to determine the central region R1 and the outer peripheral regions R2 in the XY section.

Subsequently, the composite bulk member 20 is distinguished into the conductive fibers 21, the dielectric layer 22, the conductor layer 23, and the filling resin (space 24) by image processing (with the use of EDX analysis in combination as necessary, the same shall apply hereinafter), and the area occupancy proportions S₁₁ and S₂₁ are then calculated in the same manner as the area occupancy proportions S₁₃ and S₂₃.

### <Others>

Whether the SEM image of the section (No. 1) used as mentioned above is an SEM image of a section in the thickness direction of the substrate 10 or not can be confirmed with the thickness and width of the substrate 10 being observed. If the thickness of the substrate 10, measured from the SEM image, is larger than the original thickness of the substrate, it can be determined that the section is not a section in the thickness direction. “Being larger than the original thickness of the substrate” means that the thickness of the substrate 10 in the SEM image is 5% or more larger than the original thickness of the substrate 10. In addition, if the width of the substrate 10, measured from the SEM image, is smaller than the original width of the substrate (the distance between two intersections of: a straight line passing through the center of the substrate; and both ends of the substrate), it can be determined that the section is not a section in the thickness direction. “Being smaller than the original width of the substrate” means that the width of the substrate 10 in the SEM image is 5% or more smaller than the original width of the substrate 10.

From the viewpoint of capable of confirming that the SEM image is one in a section in the thickness direction, the field of view for the observation by the SEM is desirably wide (for example, 5 μm×5 μm or more) to the extent that the surface 10a, back surface 10b, and both ends of the substrate 10 can be confirmed. In contrast, the observation field of view for identifying and/or distinguishing the constituent elements of the composite bulk member 20 or calculating the area occupancy proportions may be narrower (for example, about 1 μm×1 μm).

Whether the SEM image of the XY section used as mentioned above is an SEM image of a section in parallel with the in-plane direction of the substrate 10 or not can be confirmed with the sectional shape of the conductive fiber 21. At the first position mentioned above, most of the conductive fibers 21 extend in the Z direction, and the sectional shapes thereof are substantially circular. Thus, when the section of the conductive fiber 21 is flattened, it can be determined that the section is not an XY section. The fact that “the section of the conductive fiber 21 is flattened” means that the ratio (major axis/minor axis) of the major axis of the section of the conductive fiber 21 to the minor axis thereof is 1.41 or more. The major axis is the longest one of diameters passing through the center of the section of the conductive fiber 21. The minor axis is the shortest one of diameters passing through the center of the section of the conductive fiber 21. The center of the section of the conductive fiber 21 is the center of the smallest circle enclosing the section of the conductive fiber 21.

The respective constituent elements will be described below.

### <<Conductive Fiber>>

In the present disclosure, the conductive fiber 21 is not particularly limited as long as the longitudinal direction dimension (length) thereof is (preferably significantly) larger than the maximum sectional dimension of a section perpendicular to the longitudinal direction, or the conductive fiber 21 has the form of a schematically elongated thread.

The average length of the conductive fibers 21 may be longer in terms of being capable of increasing the capacitance density per area. The average length of the conductive fibers 21 can be, for example, several μm or more, 20 μm or more, 50 μm or more, 100 μm or more, 500 μm or more, 750 μm or more, 1000 μm or more, or 2000 μm or more. The upper limit of the average length of the conductive fibers 21 can be appropriately selected, and the lengths of the conductive fibers 21 can be, for example, 10 mm or less, 5 mm or less, or 3 mm or less. In one aspect, the average length of the conductive fibers 21 is 50 μm or more. The average length of the conductive fibers 21 may be 50 μm to 3 mm.

The average length of the conductive fibers 21 can be calculated from the SEM image of the XZ section (No. 1) mentioned above. The average length of the conductive fibers 21 is the average value of the lengths of at least five or more of the conductive fibers 21.

The average number density (referred to also as “average number density”) of the conductive fibers 21 may be higher in terms of being capable of increasing the capacitance density per area. The average number density of the conductive fibers 21 may be, for example, 10⁸ fibers/cm² or more. The average number density of the conductive fibers 21 may be, for example, 10¹³ fibers/cm² or less.

In particular, the average length of the conductive fibers 21 may be 50 μm or more, and the average number density thereof may be 10⁸ fibers/cm² or more. Thus, in the outer peripheral region R2, the inclined or bent conductive fibers 21 are more likely to come into contact with the other conductive fibers 21, thereby making the strength of the composite bulk member 20 more likely to be increased.

### Method for Calculating Average Number Density

The average number density of the conductive fibers 21 is calculated in the following manner with the use of the SEM image of the XY section used for the calculation of the area occupancy proportions S₁₃ and S₂₃. In the SEM image, the outer edge of the composite bulk member 20 is determined in the same manner as mentioned above. The number of the conductive fibers 21 present in a part (for example, a region of 5 μm×5 μm) of the determined composite bulk member 20 is counted to determine the number (number density) of the conductive fibers 21 per unit area. Such an operation is repeated to obtain the number density in five or more fields of view, and the average value thereof is defined as an average number density N in the composite bulk member 20.

The maximum sectional dimension of the conductive fiber 21 can be, for example, 0.1 nm or more, 1 nm or more, or 10 nm or more. The maximum sectional dimension of the conductive fiber 21 can be, for example, 1 nm or more, or 10 nm or more. The maximum sectional dimension of the conductive fiber 21 can be less than 1000 nm, 800 nm or less, or 600 nm or less.

The maximum sectional dimension of the conductive fiber 21 can be calculated from the SEM image of the XY section used for the calculation of the area occupancy proportions S₁₃ and S₂₃. The maximum sectional dimension of the conductive fiber 21 is the average value of the maximum sectional dimensions of at least 5 or more of the conductive fibers 21.

The conductive fibers 21 may be conductive nanofibers (with a maximum sectional dimension of nanoscale (1 nm to less than 1000 nm)). The conductive nanofibers may be, for example, conductive nanotubes (hollow, preferably cylindrical) or conductive nanorods (solid, preferably columnar). Nanorods with electrical conductivity (including semiconductivity) are also referred to as nanowires.

Examples of the conductive nanofibers that can be used according to the present disclosure include carbon nanofibers. Examples of the conductive nanotubes that can be used according to the present disclosure include metal-based nanotubes, organic conductive nanotubes, and inorganic conductive nanotubes. Typically, the conductive nanotubes can be carbon nanotubes or titania carbon nanotubes. Examples of the conductive nanorods (nanowires) that can be used according to the present disclosure include silicon nanowires, metal nanowires (in particular, silver nanowires), and conductive polymer wires. The conductive fibers 21 with the strength of 5 MPa/(nm)² to 150 Gpa/(nm)² is desirable.

Above all, the conductive fibers 21 may be carbon nanotubes. Carbon nanotubes have electrical conductivity and thermal conductivity.

The chirality of the carbon nanotubes is not particularly limited, and may have either a semiconductor type or a metal type, or a mixture thereof may be used. From the viewpoint of reducing the resistance value, the ratio of the metal type is preferably high.

The number of layers of the carbon nanotube is not particularly limited, and the carbon nanotube may be either a SWCNT (single-walled carbon nanotube) that has one layer or a MWCNT (multi-walled carbon nanotube) that has two or more layers.

The plurality of conductive fibers 21 may be vertically aligned carbon nanotubes (VACNTs). A VACNT has a large specific surface area. In addition, VACNTs can be manufactured by growth of the VACNTs vertically aligned on the substrate 10 as described later, and thus have the advantage of facilitating the control the maximum height Hₘₐₓ, the width W₃, the width W₄, and the like.

### <<Substrate>>

The substrate 10 has two main surfaces (surface 10a and back surface 10b) that face each other, and may have the form of, for example, a plate (substrate), a foil, a film, a block, or the like.

The material constituting the substrate 10 can be selected appropriately, as long as the material has electrical conductivity, and can be electrically connected to the plurality of conductive fibers 21. The material can be, for example, a semiconductor material such as silicon, a conductive material such as a metal (copper, aluminum, or nickel), or an insulating (or relatively poorly conductive) material such as a ceramic (silicon oxide) or a resin. The substrate 10 may be composed of one type of material, or composed of a mixture of two or more types of materials, or may be a composite composed of two or more types of materials. The material constituting the substrate 10 is preferably a metal because the metal is easily used as a contact with the outside, is capable of reducing the resistance value, and can withstand high temperatures.

The thickness of the substrate 10 is not particularly limited, and can vary depending on the application of the capacitor 1. The substrate 10 may be provided with an electrode for making contact with the outside and a wiring for ensuring electrical conduction. The outer shape of the substrate 10 viewed from the Z direction may be, for example, a circle, an ellipse, or a polygon.

### <<Dielectric Layer>>

The dielectric material constituting the dielectric layer 22 can be selected appropriately. Examples thereof include a silicon dioxide, an aluminum oxide, a silicon nitride, a tantalum oxide, a hafnium oxide, a barium titanate, and a lead zirconate titanate. These materials may be used alone, or two or more thereof may be used (for example, as a laminate).

The thickness of the dielectric layer 22 may be 10 nm or more, and may be 15 nm or more. The thickness of the dielectric layer is 10 nm or more, thereby making it possible to enhance the insulation property and allowing leakage current to be reduced. The thickness of the dielectric layer 22 may be 1 μm or less, 100 nm or less, or 70 nm or less. The thickness of the dielectric layer 22 is 1 μm or less, thereby allowing a higher electrostatic capacitance to be obtained. In one aspect, the thickness of the dielectric layer 22 is 10 nm to 1 μm.

The thickness of the dielectric layer 22 can be calculated from the SEM image of the XY section used for the calculation of the area occupancy proportions S₁₃ and S₂₃. The thickness of the dielectric layer 22 is the average value of the thicknesses of the dielectric layer 22 covering at least five or more of the conductive fibers 21.

If present, the material constituting the dielectric part 22a and the thickness of dielectric part 22a can be the same as those of the dielectric layer 22.

### <<Conductor Layer>>

Examples of the conductive material constituting the conductor layer 23 include a metal, a conductive polymer (which is a polymer material with conductivity and/or imparted with conductivity, and is referred to also as an organic conductive material). These materials may be used alone, or two or more thereof may be used. The conductor layer 23 may be a laminate of multiple layers that differ in conductive material.

Examples of the metal include silver, gold, copper, platinum, aluminum, and an alloy containing at least two thereof. Examples of the conductive polymer include a PEDOT (polyethylene dioxythiophene), a PPy (polypyrrole), and a PANI (polyaniline), and these polymers may be appropriately doped with a dopant such as an organic sulfonic acid-based compound, for example, a polyvinyl sulfonic acid, a polystyrene sulfonic acid, a polyallyl sulfonic acid, a polyacrylic sulfonic acid, a polymethacrylic sulfonic acid, a poly-2-acrylamide-2-methylpropane sulfonic acid, or a polyisoprene sulfonic acid.

The thickness of the conductor layer 23 may be 3 nm or more, and may be 10 nm or more. The thickness of the conductor layer 23 is 3 nm or more, thereby allowing the resistance value of the conductor layer 23 itself to be reduced. The thickness of the conductor layer 23 may be 500 nm or less, and may be 100 nm or less. In one aspect, the thickness of the conductor layer 23 is 3 nm to 500 nm.

The thickness of the conductor layer 23 can be calculated from the SEM image of the XY section used for the calculation of the area occupancy proportions S₁₃ and S₂₃. The thickness of the conductor layer 23 is the average value of the thicknesses of the conductor layer 23 covering at least five or more of the conductive fibers 21.

If present, the material constituting the conductor part 23a and the thickness of conductor part 23a can be the same as those of the conductor layer 23.

### <<Space>>

The space 24 is formed among the covered conductive fibers 21. In the section in the thickness direction and the XY section, the space 24 in the outer peripheral region R2 is smaller than the central region R1. When the space 24 becomes smaller, the composite bulk member 20 is more likely to be kept from being deformed, and thus less likely to be peeled off from the substrate 10.

### <<Conductive Member>>

The capacitor 1 can have the conductive member in contact with the conductor layer 23. The conductive member is electrically connected to the conductor layer 23, and plays a role for extending the electrode to the outside of the capacitor 1.

The conductive member has no contact with the conductive fibers 21, the dielectric layer 22, or the substrate 10. The boundary between the conductive member and the conductor layer 23 can be confirmed with an SEM image. Alternatively, the boundary between the conductive member and the conductor layer 23 can be identified from elemental analysis by EDX. Furthermore, the boundary between the conductive member and the conductor layer 23 may be determined from the thickness of the conductor layer 23 of a part that has no contact with the conductive member.

The conductive member is formed, for example, by applying/supplying a carbon paste or a conductive polymer material to a predetermined surface/part. The carbon paste and the conductive polymer material are typically relatively high in viscosity, and are thus less likely to penetrate into the space 24 and less likely to reach deep parts (for example, the surface 10a of the substrate 10) of the space 24. Accordingly, the space 24 is maintained among the covered conductive fibers 21.

### (Manufacturing Method)

The capacitor 1 according to the present embodiment can be obtained, for example, by a manufacturing method including the following:
preparing a forest including a plurality of conductive fibers 21 disposed on the surface 10a of the substrate 10 and each directly joined, at one end thereof, to the substrate 10;
tilting the conductive fibers 21 outside the forest towards the center;
forming the dielectric layer 22 (and the dielectric part 22a if present, the same shall apply hereinafter) covering the surface of the plurality of conductive fibers 21 by a sol-gel method; and
forming the conductor layer 23 (and conductor part 23a if present, the same shall apply hereinafter) covering the surface of the dielectric layer 22.

Hereinafter, the steps (a) to (d) will be described in more detail.

### Step (a)

First prepared is a forest including a plurality of vertically aligned carbon nanotubes (VACNTs) disposed on the substrate 10 and each directly joined, at one end thereof, to the substrate 10.

The step (a) can be performed by applying a catalyst onto the surface 10a of the substrate 10 and causing a plurality of VACNTs to grow from the surface 10a (in other words, directly synthesizing the plurality of VACNTs on the substrate 10). More details are as follows.

The substrate 10 may be a synthetic substrate for causing VACNTs to grow. In general, the material of the synthetic substrate is not particularly limited, and for example, silicon oxide, silicon, gallium arsenide, aluminum, or SUS can be used. In the present embodiment, the substrate 10 with conductivity is used as the synthetic substrate.

First, a catalyst is attached to the surface 10a of the substrate 10. As the catalyst, iron, nickel, platinum, cobalt, an alloy containing these metals, or the like is used. Methods such as chemical vapor deposition (CVD), sputtering, physical vapor deposition (PVD), atomic layer deposition (ALD) can be used for the method for attaching the catalyst to the substrate 10, and in some cases, such a technique may be combined with a technique such as lithography or etching.

Then, VACNTs are allowed to grow (directly synthesized) on the substrate 10 with the catalyst attached thereto. The method for the VACNT growth is not particularly limited, and CVD, plasma-enhanced CVD, or the like can be used under heating as necessary. The gas used is not particularly limited, and for example, at least one selected from the group consisting of carbon monoxide, methane, ethylene, and acetylene, or a mixture of at least one thereof and hydrogen and/or ammonia can be used. If desired, moisture may be present in the ambient atmosphere for VACNT growth. Thus, VACNTs grow with the catalyst as a nucleus on the substrate 10. The end of the VACNT on the side of the substrate 10 with the catalyst attached is a fixed end that is fixed to the substrate 10 (typically with the catalyst interposed therebetween), and the opposite end of the VACNT is a free end that is a growth point. The length and diameter of the VACNT may vary depending on changes in parameters such as a gas concentration, a gas flow rate, and a temperature. More specifically, the length and diameter of the VACNT can be adjusted by appropriately selecting these parameters.

As a result, a forest of VACNTs (conductive fibers 21) is prepared on the substrate 10. Strictly speaking, the length of each of VACNTs in the obtained forest can vary (for example, cause in-plane variations) on the free end side due to a difference in growth rate or the like. When the VACNTs are allowed to grow on the substrate 10 with the catalyst attached thereto, the growth of some carbon nanotubes (CNTs) may be stopped due to the catalyst deactivated in the process of the VACNT synthesis. The CNTs whose growth is stopped are entangled with the subsequently growing CNTs and then pulled, thereby making the fixed ends away from the substrate 10 and then pulled up toward the tips of the VACNTs.

The plurality of VACNTs (conductive fibers 21) obtained as mentioned above are disposed on the substrate 10, and each directly joined, at one end thereof, to the substrate 10. As understood from the above-mentioned description, however, some of the CNTs may be indirectly joined to the substrate 10.

### Step (b)

Next, the VACNTs at an edge of the forest is tilted toward the center. Thus, in a section of the obtained composite bulk member 20 in the thickness direction, the length (W₁) of the upper side is smaller than the length (W₂) of the lower side (W₁<W₂).

Immersing the forest in a suitable solvent allows the VACNTs at the edge of the forest be to tilted towards the center. Immersing the forest in an appropriate solvent makes the VACNTs, particularly outside the forest more likely to be agglomerated with each other. In contrast, the VACNTs near the center of the forest are likely to be kept upright. As a result, the VACNTs at the edge are inclined toward the center.

The solvent is selected in consideration of the wettability of the VACNTs. When the wettability of the VACNTs is excessively low, the agglomeration of the VACNTs are less likely to proceed. In contrast, when the wettability of the VACNTs is excessively high, the agglomeration of the VACNTs excessively proceeds, thereby making the composite bulk member 20 suitable for the capacitor 1 less likely to be obtained. Examples of the suitable solvent include water, ethanol, isopropanol, and acetone. Above all, ethanol may be used.

A surfactant may be added to the solvent. Thus, the wettability of the VACNTs is easily adjusted. The surfactant may be anionic. The surfactant is selected appropriately in consideration of the charge and molecular weight of the hydrophilic group. Examples of the surfactant include a sodium dodecyl sulfate, a cetyltrimethylammonium bromide, and a sodium dodecylbenzenesulfonate. The amount of the surfactant added is set appropriately in consideration of the wettability of the VACNTs.

A material for the dielectric layer 22 may be added to the solvent. Thus, the step (c) can be performed with the use of the bath used in the step (b) as it is.

The conditions for the immersion are also set in consideration of the wettability of the VACNTs. The immersion may be performed, in terms of suppressing excessive agglomeration, by putting the substrate 10 provided with a forest into a solvent at room temperature (23° C.±3° C.) at a speed of 2 to 10 mm/second (typically, 5 mm/s) such that the angle formed by the substrate 10 and the liquid level is approximately 90 degrees. The forest is immersed in the solvent, and then pulled up and dried, thereby allowing the VACNTs outside the forest to be greatly inclined or bent toward the center.

The agglomeration of the forest is also described in Non-Patent Document 1.

### Step (c)

Subsequently, the dielectric layer 22 covering at least the surface of the VACNTs is formed by a sol-gel method.

A film that is formed by a liquid phase film formation method typified by a sol-gel method tends to contain therein impurities and volatile components. Such impurities and volatile components are easily desorbed by heating, and thus, the shrinkage of the film is likely to be increased, and the tensile stress applied to the composite bulk member 20 is also further increased. The composite bulk member 20 according to the present disclosure is, however, kept from being peeled from the substrate 10, also when the dielectric layer 22 is formed by the liquid phase film formation method.

The thickness of the dielectric layer 22 to be formed can be controlled by appropriately selecting or setting the conditions for implementing the sol-gel method. For example, the prepared composition of the liquid for use in the liquid phase film formation method, the solvent (for example, water, ethanol, isopropanol, or acetone) for use in the preparation, the film formation time, the stirring speed, the temperature, and the like may be selected or set appropriately.

As mentioned above, when the material for the dielectric layer 22 is added to the solvent used in the step (b), the step (b) and the step (c) are performed simultaneously or continuously in the same bath. In other words, the agglomeration of the VACNTs and the adhesion of the material for the dielectric layer 22 proceed simultaneously or continuously. The material for the dielectric layer 22 adheres to the surface of the VACNTs, thereby making the VACNTs likely to be kept appropriately agglomerated with each other, and then, further agglomeration is kept from proceeding due to subsequent drying. The step (b) and the step (c) may be performed simultaneously or continuously from the viewpoint of easily controlling the agglomeration as described above. In this case, the film formation time may be 1 to 3 hours (typically 1.5 hours), and the stirring speed may be 150 to 500 rpm (typically 300 rpm). The other conditions may be the same as the conditions for the immersion in the step (b).

Thereafter, the dielectric layer 22 is formed by drying for the removal of the solvent.

### Step (d)

Subsequently, the conductor layer 23 covering the surface of the dielectric layer 22 is formed.

The film formation method for the conductor layer 23 is not particularly limited, and a liquid phase film formation method, a vapor phase film formation method, and a combination thereof may be used. The liquid phase film formation method can be, for example, a sol-gel method, plating, or the like. The vapor phase film formation method can be ALD, sputtering, CVD, or the like.

For example, the conductor layer 23 can be formed by a liquid phase film formation method with the use of a conductive polymer. More specifically, the conductor layer 23 can be formed by applying/supplying (for example, performing application, immersion, or the like), to a predetermined surface/part, a liquid composition that has a conductive polymer dissolved or dispersed in an organic solvent. The conductive polymer is easily allowed to penetrate into space formed among the conductive fibers 21 covered with the dielectric layer 22, and the conductor layer 23 can be formed appropriately also in deep parts (for example, bottom parts) of the space.

As described above, the capacitor 1 shown in FIGS. 1, 2, 3A, and 3B can be manufactured.

### Embodiment 2

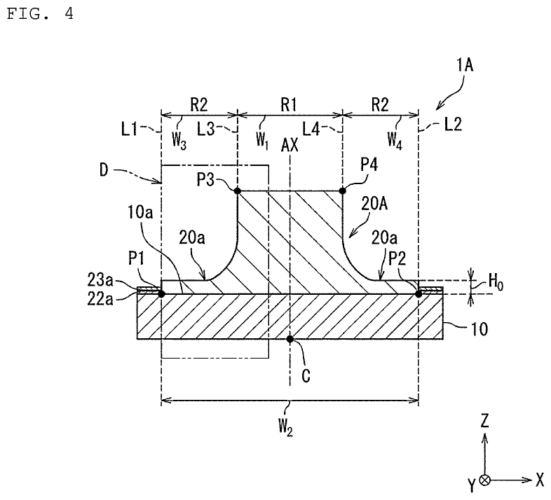

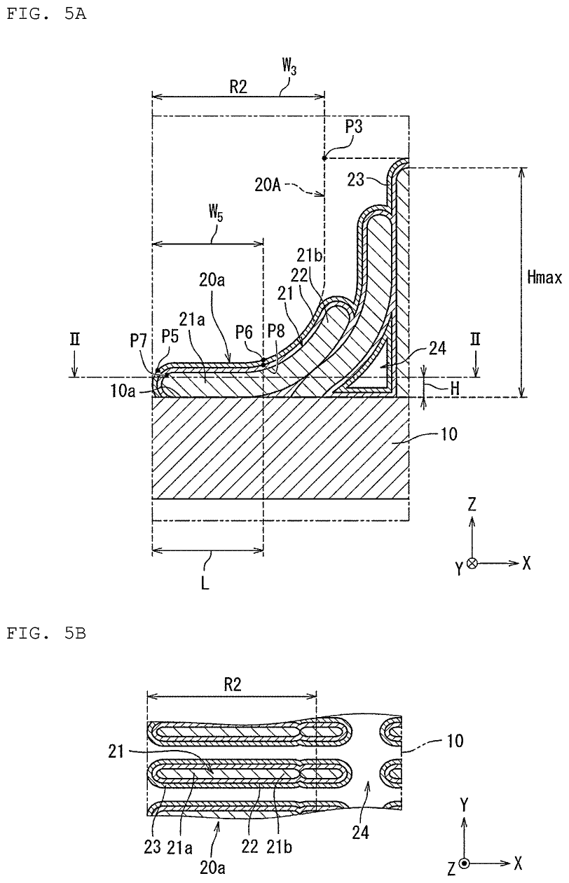

FIG. 4 is a schematic sectional view of a capacitor according to Embodiment 2. FIG. 4 is a sectional view corresponding to FIG. 1. FIG. 5A is an enlarged view of a part D in FIG. 4, corresponding to FIG. 3A. FIG. 5B is a sectional view of the part D in FIG. 4 in an in-plane direction of a substrate. FIG. 5B corresponds to the II-II section of FIG. 5A. For the sake of convenience, FIGS. 5A and 5B show only parts of a substrate 10, conductive fibers 21, a dielectric layer 22, and a conductor layer 23.

Embodiment 2 is different from Embodiment 1 in the outer shape of the composite bulk member. This different configuration will be described below. The other configurations are the same as those of Embodiment 1, and are denoted by the same reference symbols as those of the Embodiment 1, and will be omitted from description.

### <Outer Edge>

As shown in FIG. 4, for a capacitor 1A according to Embodiment 2, a composite bulk member 20A has outer edges 20a extending in parallel with the width direction in outer peripheral regions R2 of a section in the thickness direction. The outer edge 20a corresponds to at least a part of the outer peripheral region R2, and includes at least a part of the outer edge of the composite bulk member 20A.

Unlike the dielectric part 22a or the conductor part 23a, the outer edges 20a includes the conductive fibers 21. As shown in FIGS. 5A and 5B, at the outer edge 20a of the XZ section, the conductive fiber 21 includes a first part 21a extending in parallel with the X direction. More specifically, at the outer edge 20a, the conductive fiber 21 is laid such that at least a part thereof extends in parallel with the X direction. Thus, the space 24 present in the outer edge 20a is further smaller. Accordingly, the composite bulk member 20A is much less likely to be deformed, and is further kept from being peeled from the substrate 10.

In addition, the first part 21a increases the area of contact between the conductive fiber 21 and the substrate 10 to decreases the area contact between the dielectric layer 22 and the substrate 10, thus reducing the influence of the difference in thermal expansion, and then further keeping the composite bulk member 20A from being peeled off.

When the conductive fiber 21 has high strength, the function of the fiber 21 as a core material is effectively fulfilled by the first part 21a, and cracks are also kept from being generated in the composite bulk member 20A due to tensile stress. Furthermore, the area of contact between the conductive fibers 21 at the outer edge 20a is increased, thereby increasing the mechanical strength of the composite bulk member 20A, and then further enhancing the effect of keeping the composite bulk member 20A from being deformed.

Although not shown in FIG. 5A, the covered conductive fiber 21 is present near the left apex P3 of the composite bulk member 20, and the left apex P3 is determined by the covered conductive fiber 21.

The term “parallel” in relation to the outer edge 20a means that an acute angle θa (not shown) formed by a tangent line on the surface (that is, the surface of the conductor layer 23) of the composite bulk member 20A and the surface 10a of the substrate 10 is 30 degrees or less. The upper surface of the outer edge 20a may have fine irregularities caused by the dielectric layer 22 and/or the conductor layer 23. The acute angle θa of 30 degrees or less in the case of observation in a field of view of 5 μm×5 μm or more may be considered as the outer edge 20a extending in parallel with the width direction, without considering the fine irregularities.

The term “parallel” in relation to the first part 21a means that an acute angle θb (not shown) formed by the upper surface of the conductive fiber 21 and the surface 10a of the substrate 10 is 30 degrees or less.

As shown in FIG. 5A, the conductive fiber 21 may have a second part 21b other than the first part 21a in the outer peripheral region R2. The second part 21b is a part of the conductive fiber 21 extending in the Z direction or in a direction that forms, with the Z direction, an acute angle (not shown) of more than 0 degrees and less than 60 degrees. At the outer edge 20a, the second part 21b may be disposed together with the first part 21a of the conductive fiber 21.

The length L and maximum height Hₘₐₓ of the first part 21a may satisfy the following relational expression:

$$L \geq 0.8 \times {H}_{max}$$

The maximum height Hₘₐₓ may be considered to represent the entire length of one of the conductive fibers 21. When 80% or more of the total length of the conductive fiber 21 extends in parallel with the X direction, the area of contact between the conductive fiber 21 and the substrate 10 is further increased, thereby further improving the effect of keeping the composite bulk member 20A from being peeled from the substrate 10. In particular, the length L and the maximum height Hₘₐₓ may satisfy a relationship of L≥1.0×Hₘₐₓ. The length L and the maximum height Hₘₐₓ may satisfy a relationship of L≤10×Hₘₐₓ.

At the outer edge 20a, the plurality of conductive fibers 21 may each have the first part 21a. The first part 21a of at least one of the plurality of conductive fiber 21 has only to satisfy the relational expression (L≥0.8×Hₘₐₓ).

### Method for Determining First Part 21a

The first part 21a is determined as follows with the use of an SEM image of a section (for example, an XZ section) of the composite bulk member 20A in the thickness direction. First, the outer peripheral region R2 in the XZ section is determined in the same manner as mentioned above. At the conductive fiber 21 present in the outer peripheral region R2, the acute angle θb formed by the upper surface of the conductive fiber 21 and the surface 10a of the substrate 10 is measured from the outer edge side of the composite bulk member 20A toward the central axis AX. The observation field of view in this case may be any field as long as the whole of one of the outer peripheral regions R2 can be checked.

As shown in FIG. 5A, a point at which the acute angle θb is 30 degrees or less first is one end P7 of the first part 21a. When P7 is located in the vicinity of the outer edge of the outer peripheral region R2, one end of the first part 21a may be regarded as the outermost part of the conductive fiber 21. In FIG. 5A, the end P7 is located in the vicinity of the outer edge of the outer peripheral region R2, and the outermost part of the conductive fiber 21 is regarded as one end of the first part 21a.

A point at which the acute angle θb is greater than 30 degrees and after which the acute angle θb is not found to be decreased is the other end P8 of the first part 21a. A part of the conductive fiber 21, corresponding to a region sandwiched between the one end P7 or the outer end of the conductive fiber 21 and the other end P8, is the first part 21a.

### Method for Determining Outer Edge 20a

The outer edge 20a is determined as follows from the SEM image of the XZ section used for the determination of the first part 21a. In the SEM image, the acute angle θa formed by the tangent line on the surface of the composite bulk member 20A and the surface 10a of the substrate 10 is measured from the outer edge of the composite bulk member 20A toward the central axis AX. As mentioned above, the observation field of view in this case is 5 μm×5 μm or more.

As shown in FIG. 5A, a point at which the acute angle θa is 30 degrees or less first is one end P5 of the outer edge 20a on the upper surface side. When P5 is located in the vicinity of the outer edge of the outer peripheral region R2, one end of the outer edge 20a may be regarded as the outermost part of the outer peripheral region R2. In FIG. 5A, the end P5 is located in the vicinity of the outer edge of the outer peripheral region R2, the outermost part of the outer peripheral region R2 is regarded as one end of the outer edge 20a.

A point at which the acute angle θa is greater than 30 degrees and after which the acute angle θa is not found to be decreased is the other end P6 of the outer edge 20a on the upper surface side. The composite bulk member 20A corresponding to a region sandwiched between the one end P5 or the one end of the outer peripheral region R2 and the other end P6 is the outer edge 20a.

The outer edge 20a has only to be present in one section in the thickness direction. The outer edge 20a may be present in multiple different sections in the thickness direction, may be present in three or more different sections in the thickness direction, and may be preset in any section in the thickness direction. In this case, the composite bulk member 20A is further kept from being peeled from the substrate 10.

In the section in the thickness direction, the outer edge 20a may be present in the outer peripheral region R2 on at least one of one side and the other side. The outer edge 20a may in be present in the outer peripheral regions R2 on both of one side and the other side. The first part 21a of the conductive fiber 21 has only to be disposed for a part of the outer edge 20a, and may be disposed over the whole outer edge 20a.

The outer edge 20a may or may not coincide with the outer peripheral region R2. The width W₅ of the outer edge 20a may be 30% to 100% of the width W₃ or width W₄ of the outer peripheral region. The width W₅ of the outer edge 20a may be 40% or more of, or may be 50% or more of the width W₃ or width W₄ of the outer peripheral region.

The width W₅ of the outer edge 20a is determined as follows with the use of the SEM image of the XZ section used for determining the outer edge 20a. The distance in the X direction between a straight line including the one end P5 of the outer edge 20a, determined as mentioned above, or the one end of the outer peripheral region R2 and extending in the Z direction and a straight line including the other end P6 of the outer edge 20a and extending in the Z direction is the width W₅.

### Method for Determining Length L

The length L of the first part 21a is the length of the first part 21a in the X direction. The length L of the first part 21a is determined as follows with the use of the SEM image of the XZ section used for determining the outer edge 20a. The distance in the X direction between a straight line including the one end P7 of the first part 21a, determined as mentioned above, or the outer end of the conductive fiber 21 and extending in the Z direction and a straight line including the other end P8 of the first part 21a and extending in the Z direction is the length L.

As shown in FIG. 4, the outer edge 20a has a height H_{O} in the XZ section. The height H_{O} and the maximum height Hₘₐₓ may satisfy following relational expression:

$${H}_{o} \leq 0.2 \times {H}_{max}$$

### Method for Determining Height H_{O}

The height H_{O} of the outer edge 20a may be 0.01 times or less as large as the maximum height Hₘₐₓ of the conductive fiber 21. From the viewpoint of capacitance, the height H_{O} of the outer edge 20a may be 0.0001 times or more as large as the maximum height Hₘₐₓ of the conductive fiber 21.

The height H_{O} of the outer edge 20a is measured in the follow manner with the use of the XZ section used for determining the outer edge 20a. In the section, the outer edge 20a is already determined. Determined is the distance in the Z direction from the surface 10a of the substrate 10 to an arbitrary point on the upper surface of the outer edge 20a. Such an operation is repeated to obtain the distance at five or more points, and the average value thereof is defined as the height H_{O} of the outer edge 20a.

### <Area Occupancy Proportion S₂₄>

In the section in the thickness direction, the outer edge 20a includes a part where the total area occupancy proportion S₂₄ of the conductive fibers 21 and dielectric layer 22 is higher than the total area occupancy proportion S₁₁ of the conductive fibers 21 and the dielectric layer 22 in the central region R1. More specifically, S₂₄/S₁₁≥1.05 is satisfied. The area occupancy proportion S₂₄ is calculated in the same manner as the area occupancy proportion S₂₁.

The above-mentioned relationship between the area occupancy proportions S₁₁ and S₂₄ has only to be satisfied in one section in the thickness direction. The above-mentioned relationship may be satisfied in multiple different sections in the thickness direction, may be satisfied in three or more different sections in the thickness direction, and may be satisfied in any section in the thickness direction.

While the two embodiments of the present disclosure have been described in detail above, the present disclosure is not limited thereto. For example, any two or more of the respective features of the embodiments describe above may be combined.

In the composite bulk members 20 and 20A according to the embodiments described above, the length of the upper side s1 is equal to the width W₁, and the length of the lower side s2 is equal to the width W₂, but the relations are not limited thereto. The length of the upper side s1 may be longer than the width W₁, for example, when the upper side s1 and the lower side s2 are not parallel to each other.

In the composite bulk member 20 according to the embodiment described above, the angle θ1 of the interior angle formed by the lower side s2 and the left side s3 (that is, one end side of the composite bulk member 20 in the width direction) and the angle θ2 of the interior angle formed by the lower side s2 and the right side s4 (that is, the other end side of the composite bulk member 20 in the width direction) are both less than 90 degrees, but the angles not limited thereto. At least one of the angles θ1 and θ2 of the interior angles may be less than 90 degrees. In particular, both the angles θ1 and θ2 of the interior angles may be less than 90 degrees.

In the composite bulk members 20 and 20A according to the embodiments described above, the outer peripheral regions R2 are, with the central region R1 sandwiched therebetween, disposed at the two sites at both ends in the width direction, but the disposition is not limited thereto. In the sections of the composite bulk members 20 and 20A in the thickness direction, the outer peripheral region R2 may be disposed only at one end of the central region R1 in the X direction.

In the composite bulk members 20 and 20A according to the embodiments mentioned above, the conductive fibers 21 are directly joined to the substrate 10, but the joint is not limited thereto. The conductive fibers 21 may be joined to the substrate 10, with an adhesive layer with conductivity interposed therebetween. The conductive fibers 21 may be bonded to the surface of the adhesive layer, or may be bonded to the adhesive layer by inserting ends of the conductive fibers 21 into the adhesive layer. The adhesive layer with conductivity is typically formed from a metal material.

In the composite bulk members 20 and 20A according to the embodiments described above, the conductive fibers 21 in the outer peripheral regions R2 are inclined or bent, but are not limited thereto. The conductive fibers 21 in the outer peripheral regions R2 may extend in the Z direction. In this case, the conductive fibers 21 in the outer peripheral regions R2 are shorter than the conductive fibers 21 in the central region R1.

In the composite bulk members 20 and 20A according to the embodiments described above, the conductive fibers 21 in the outer peripheral regions R2 have contact with each other, with the dielectric layer 22 interposed therebetween or without the dielectric layer 22 interposed therebetween, but the conductive fibers 21 are not limited thereto. The plurality of conductive fibers 21 in the outer peripheral region R2 may be isolated from each other.

In the capacitors A and 1A according to the embodiments described above, the conductive fibers 21 and/or the composite bulk members 20 and 20A may be present on the surface (side surface) connecting the surface 10a and the back surface 10b on the substrate 10.

In the embodiment described above, the carbon nanotubes (CNTs) have been exemplified as the conductive fiber 21 in the step (a), but the conductive fibers 21 are not limited thereto. The conductive fibers 21 may be conductive fibers other than CNTs.

In the embodiment described above, the forest is provided on the substrate 10 in the step (a), but the step is not limited thereto. The forest may be provided on another synthetic substrate, and then transferred to the substrate 10. In this case, the step (b) and the subsequent steps may be performed after the transfer. On the substrate 10, an adhesive layer may be provided.

In the embodiment described above, the sectional shape of the forest is made trapezoidal by inclining some of the conductive fibers 21 in the step (b), but the step is not limited thereto. In the step (a), the sectional shape of the forest may be made trapezoidal by reducing the degree of growth of the conductive fibers 21 constituting the edge of the forest. In this case, step (b) is omitted.

In the embodiment described above, some of the conductive fibers 21 are inclined by agglomeration in the step (b), but the inclination is not limited thereto. Some of the conductive fibers 21 may be inclined by pressing the forest from the outside toward the center.

In the embodiment described above, the dielectric layer 22 is formed by the sol-gel method in the step (c), but the method is not limited thereto. The dielectric layer 22 may be formed by a vapor phase film formation method (typically, a sputtering method). In this case, the solvent used in the step (b) is removed, and then, step (c) is performed. The dielectric layer 22 may be formed by a liquid phase film formation method (typically, a plating method) other than the sol-gel method. When the dielectric layer 22 is made of a metal oxide, a method of plating in combination with a surface oxidation treatment may be used.

### EXAMPLES

The present disclosure will be more specifically described with reference to the following manufacturing example, but the present disclosure is not limited thereto.

### Manufacturing Example 1

The capacitor 1A including the composite bulk member 20A according to the embodiment described above was manufactured.

### Preparation of Forest

A catalyst was applied onto the surface of a Si substrate 10, and VACNTs were allowed to grow to obtain a forest 200. The maximum height (maximum height Hₘₐₓ) of the forest 200 was 105 μm, and the outer diameter of the CNT was about 20 nm. The number density of CNTs in the forest was 3.99×10⁸ fibers/cm². The number density of CNTs in the forest 200 can be regarded as the average number density of the conductive fibers 21 in the composite bulk member 20.

### (2) Inclination of CNTs and Formation of Dielectric Layer

The substrate 10 provided with the forest 200 was immersed in a raw material solution containing sodium dodecyl sulfate, ammonia, 3-aminopropyltriethoxysilane, and ethanol. The immersion was performed in the following manner. First, the substrate 10 provided with the forest 200 was put into the raw material liquid with a liquid temperature of room temperature (23° C.±3° C.) such that the angle formed by the substrate 10 and the liquid level of the raw material liquid was approximately 90 degrees. The putting speed was set to 5 mm/sec. The substrate was pulled up after being kept while stirring at 300 rpm for 1.5 hours at 25° C. Finally, drying was performed to form a dielectric layer 22 (SiO₂) covering the surface of the plurality of CNTs (conductive fibers 21) on the substrate 10.

### (3) Formation of Conductor Layer

Subsequently, the substrate 10 was immersed in a dispersion liquid containing PEDOT (polyethylene dioxythiophene) and PSS (polystyrene sulfonic acid) to form a conductor layer 23 (composite of PEDOT/PSS) on the dielectric layer 22. In this manner, the capacitor 1A was obtained.

The space present in the composite bulk member 20A of the obtained capacitor 1A was filled with a resin, and then, the substrate 10 was viewed from the Z direction to determine the center C of the substrate 10. Then, an XZ section including the center C was exposed by polishing. The obtained section was observed with an SEM. The average length of the fiber-shaped conductive members can be understood to be 50 μm or more, and the thickness of the dielectric layer can be understood to be 10 nm or more.

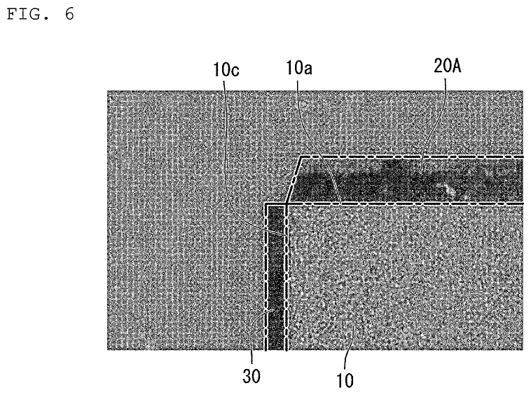

FIG. 6 shows an SEM image of a part of the section. In FIG. 6, a composite bulk member 30 is also present on a side surface 10c of the composite bulk member 20A. In FIG. 6, broken lines indicating the outer edges of the composite bulk members 20A and 30 and substrate 10 are attached for the sake of convenience.

The left bottom P1, right bottom P2, left apex P3, and right apex P4 of the composite bulk member 20A were determined in the same manner as mentioned above from an SEM image in which the whole section could be observed. The widths W₁, W₂, W₃, and W₄, and Hₘₐₓ were obtained from P1 to P4. The width W₁ was 4.76 mm, W₂ was 5.00 mm, W₂−W₁ was 240 μm, and Hₘₐₓ was 105 μm. It can be understood that the widths W₁, W₂, W₃, and W₄ satisfy the relationships of W₁<W₂, W₂−W₁≥1.6×Hₘₐₓ, and W₂>Hₘₐₓ, and the relationships of W₃≥0.8×Hₘₐₓ and W₄≥0.8×Hₘₐₓ. When the line segment formed by connecting the left bottom P1 and the right bottom P2 was considered as the lower side s2, the line segment formed by connecting the left bottom P1 and the left apex P3 was considered as the left side s3, and the line segment formed by connecting the right bottom P2 and the right apex P4 is considered as the right side s4, the angle θ1 of the interior angle formed by the lower side s2 and the left side s3 was 73.6 degrees, and the angle θ2 of the interior angle formed by the lower side s2 and the right side s4 was 54.4 degrees.

In any of sections in the thickness direction, both the outer peripheral regions R2 on one side and the other side included a part where the area occupancy proportion S₂₂ was higher than the area occupancy proportion S₁₂ of the central region R1. The area occupancy proportion satisfied the relationship of S₂₂/S₁₂≥1.36. Accordingly, both the outer peripheral regions R2 on one side and the other side can be understood to include a part where the area occupancy proportion S₂₁ is higher than the area occupancy proportion S₁₁ of the central region R1.

In at least one section in the in-plane direction, the outer peripheral region R2 included a part where the area occupancy proportion S₂₃ is higher than the area occupancy proportion S₁₃ of the central region R1. The area occupancy proportion satisfied the relationship of S₂₃/S₁₃≥1.53.

The maximum sectional dimension of the CNT, calculated from the section in the in-plane direction, was 33 nm. The thickness of the dielectric layer 22 was 51 nm. The thickness of the conductor layer 23 was 15 nm.

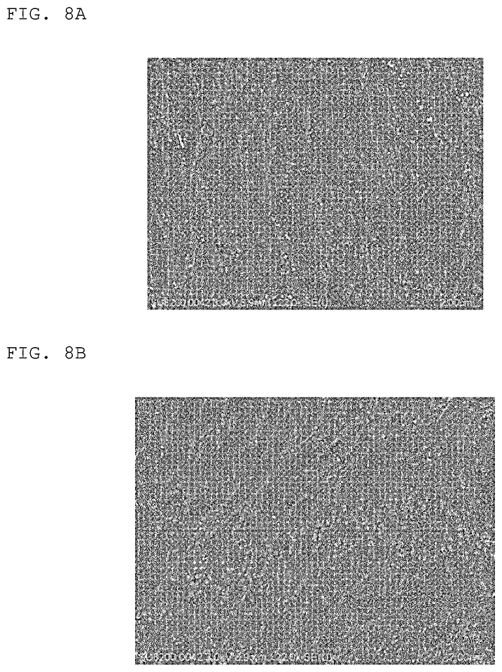

FIG. 8A is an SEM image obtained by photographing a part of the outer peripheral region in the polished XZ section of the composite bulk member obtained according to Manufacturing Example 1. FIG. 8B is an SEM image obtained by photographing a part of the central region in the polished XZ section of the composite bulk member obtained according to Manufacturing Example 1. In FIGS. 8A and 8B, parts that appear whitish in linear shapes are the conductive fibers 21 covered with the dielectric layer 22 and the conductor layer 23, and a black part is the filling resin corresponding to the space 24.

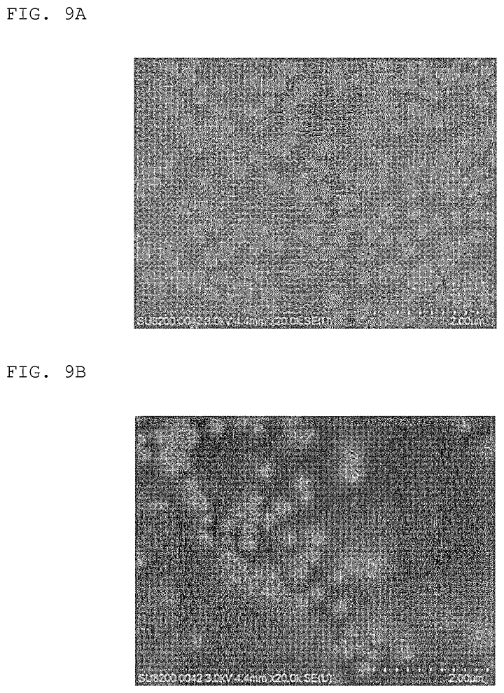

FIG. 9A is an SEM image obtained by photographing a part of the outer peripheral region in the polished XY section of the composite bulk member obtained according to Manufacturing Example 1. FIG. 9B is an SEM image obtained by photographing a part of the central region in the polished XY section of the composite bulk member obtained according to Manufacturing Example 1. In FIGS. 9A and 9B, parts that appear whitish in circular shapes are the conductive fibers 21 covered with the dielectric layer 22 and the conductor layer 23, and a black part is the filling resin corresponding to the space 24.

The capacitor according to the present disclosure can be used in any appropriate application, and particularly, can be suitably used in an application that requires high joining strength between the substrate and the composite bulk member.

<1> A capacitor including: a substrate with conductivity; a plurality of fiber-shaped conductive members on the substrate and electrically connected to the substrate; a dielectric layer covering a surface of each of the plurality of fiber-shaped conductive members; and a conductor layer covering a surface of the dielectric layer, wherein the plurality of fiber-shaped conductive members, the dielectric layer, the conductor layer, and a space among the plurality of fiber-shaped conductive members covered with the dielectric layer and the conductor layer constitute a composite bulk member, and in a section in the thickness direction of the substrate, the composite bulk member has a width W₁ on a side thereof opposite to the substrate and a width W₂ on a side thereof proximal to the substrate, with an in-plane direction of the substrate as a width direction, and the width W₁ is smaller than the width W₂.

<2> The capacitor according to <1>, wherein in the section in the thickness direction of the substrate, the fiber-shaped conductive member has a maximum height Hₘₐₓ in a central region corresponding to the width W₁, and W₂−W₁≥1.6×Hₘₐₓ.

<3> The capacitor according to <2>, wherein in the section in the thickness direction of the substrate, the composite bulk member has a width W₃ and a width W₄ respectively in outer peripheral regions on a first side and a second side opposite to the first side with the central region corresponding to the width W₁ sandwiched therebetween, and W₃≥0.8×Hₘₐₓ and W₄≥0.8×Hₘₐₓ.

<4> The capacitor according to any one of <1> to <3>, wherein in the section in the thickness direction of the substrate, in the outer peripheral region of the composite bulk member on at least one of the first side and the second side with the central region corresponding to the width W₁ sandwiched therebetween, the fiber-shaped conductive member has a first part extending in parallel with the in-plane direction of the substrate.

<5> The capacitor according to <4>, wherein in the section in the thickness direction of the substrate, the fiber-shaped conductive member has a maximum height Hₘₐₓ in the central region, and the length L of the first part and the maximum height Hₘₐₓ satisfy L≥0.8×Hₘₐₓ.

<6> The capacitor according to any one of <1> to <5>, wherein in one section in the thickness direction of the substrate, the outer peripheral region on at least one of the first side and the second side with the central region corresponding to the width W₁ sandwiched therebetween includes a part where a first total area occupancy proportion S₂₂ of the fiber-shaped conductive members, the dielectric layer, and the conductor layer is higher than a second total area occupancy proportion S₁₂ of the fiber-shaped conductive members, the dielectric layer, and the conductor layer in the central region.

<7> The capacitor according to any one of <1> to <6>, wherein in one section in the thickness direction of the substrate, both the outer peripheral regions on the first side and the second side with the central region corresponding to the width W₁ sandwiched therebetween include a part where the first total area occupancy proportion S₂₂ of the fiber-shaped conductive members, the dielectric layer, and the conductor layer is higher than the second total area occupancy proportion S₁₂ of the fiber-shaped conductive members, the dielectric layer, and the conductor layer in the central region.

<8> The capacitor according to any one of <1> to <7>, wherein in multiple sections in the thickness direction of the substrate, the outer peripheral region on at least one of the first side and the second side with the central region corresponding to the width W₁ sandwiched therebetween includes a part where the first total area occupancy proportion S₂₂ of the fiber-shaped conductive members, the dielectric layer, and the conductor layer is higher than the second total area occupancy proportion S₁₂ of the fiber-shaped conductive members, the dielectric layer, and the conductor layer in the central region.

<9> The capacitor according to any one of <1> to <8>, wherein in one section in the in-plane direction of the substrate, the outer peripheral region on at least one of the first side and the second side with the central region corresponding to the width W₁ sandwiched therebetween includes a part where a third total area occupancy proportion S₂₃ of the fiber-shaped conductive members, the dielectric layer, and the conductor layer is higher than a fourth total area occupancy proportion S₁₃ of the fiber-shaped conductive members, the dielectric layer, and the conductor layer in the central region.

<10> The capacitor according to any one of <1> to <9>, wherein the plurality of fiber-shaped conductive members have the maximum height Hₘₐₓ in the central region corresponding to the width W₁, and the width W₂ and the maximum height Hₘₐₓ satisfy W₂>Hₘₐₓ

<11> The capacitor according to any one of <1> to <10>, wherein the dielectric layer has a thickness of 10 nm or more.

<12> The capacitor according to any one of <1> to <11>, wherein the plurality of fiber-shaped conductive members have an average number density of 10⁸ fibers/cm² or more.

<13> The capacitor according to any one of <1> to <12>, wherein the plurality of fiber-shaped conductive members have an average length of 50 μm or more.

<14> The capacitor according to any one of <1> to <13>, wherein the fiber-shaped conductive members are carbon nanotubes.

### DESCRIPTION OF REFERENCE SYMBOLS

1, 1A: Capacitor
10: Substrate
10a: Surface
10b: Back surface
10c: Side surface
20, 20A: Composite bulk member
20a: Outer edge
21: Fiber-shaped conductive member (conductive fiber)
21a: First part
21b: Second part
22: Dielectric layer
22a: Dielectric part
23: Conductor layer
23a: Conductor part
24: Space
30: Composite bulk member on side surface
100: Conventional capacitor
110: Substrate
120: Composite bulk member
200: Forest
300: Deposited product of SiO₂
L1 to L4: Sides representing outer shape of composite bulk member
P1, P2: Left and right bottoms of composite bulk member
P3, P4: Left and right apexes of composite bulk member
P5, P6: Ends of outer edge
P7, P8: Ends of first part
C: Center of substrate
R1: Central region
R2: Outer peripheral region

1. A capacitor comprising:
a substrate with conductivity;
a plurality of fiber-shaped conductive members on the substrate and electrically connected to the substrate;
a dielectric layer covering a surface of each of the plurality of fiber-shaped conductive members; and
a conductor layer covering a surface of the dielectric layer,
wherein
the plurality of fiber-shaped conductive members, the dielectric layer, the conductor layer, and a space among the plurality of fiber-shaped conductive members covered with the dielectric layer and the conductor layer constitute a composite bulk member, and
in a section in a thickness direction of the substrate, the composite bulk member has a width W₁ on a side thereof opposite to the substrate and a width W₂ on a side thereof proximal to the substrate, with an in-plane direction of the substrate as a width direction, and the width W₁ is smaller than the width W₂.

2. The capacitor according to claim 1, wherein in the section in the thickness direction of the substrate, each of the fiber-shaped conductive members has a maximum height Hₘₐₓ in a central region corresponding to the width W₁, and W₂−W₁≥1.6×Hₘₐₓ.

3. The capacitor according to claim 2, wherein in the section in the thickness direction of the substrate, the composite bulk member has a width W₃ and a width W₄ respectively in outer peripheral regions on a first side and a second side opposite the first side with the central region corresponding to the width W₁ sandwiched therebetween, and W₃≥0.8×Hₘₐₓ and W₄≥0.8×Hₘₐₓ.

4. The capacitor according to claim 1, wherein in the section in the thickness direction of the substrate,
in an outer peripheral region of the composite bulk member on at least one of a first side and a second side with a central region corresponding to the width W₁ sandwiched therebetween,
each of the fiber-shaped conductive members has a first part extending in parallel with the in-plane direction of the substrate.

5. The capacitor according to claim 4, wherein in the section in the thickness direction of the substrate,
each of the fiber-shaped conductive members has a maximum height Hₘₐₓ in the central region, and
a length L of the first part and the maximum height Hₘₐₓ satisfy: L≥0.8×Hₘₐₓ.

6. The capacitor according to claim 1, wherein in the section in the thickness direction of the substrate, an outer peripheral region on at least one of a first side and a second side with a central region corresponding to the width W₁ sandwiched therebetween includes a part where a first total area occupancy proportion of the fiber-shaped conductive members, the dielectric layer, and the conductor layer is higher than a second total area occupancy proportion of the fiber-shaped conductive members, the dielectric layer, and the conductor layer in the central region.

7. The capacitor according to claim 1, wherein in the section in the thickness direction of the substrate, outer peripheral regions on a first side and a second side with a central region corresponding to the width W₁ sandwiched therebetween include a part where a first total area occupancy proportion of the fiber-shaped conductive members, the dielectric layer, and the conductor layer is higher than a second total area occupancy proportion of the fiber-shaped conductive members, the dielectric layer, and the conductor layer in the central region.

8. The capacitor according to claim 1, wherein in multiple sections in the thickness direction of the substrate, an outer peripheral region on at least one of a first side and a second side with a central region corresponding to the width W₁ sandwiched therebetween includes a part where a first total area occupancy proportion of the fiber-shaped conductive members, the dielectric layer, and the conductor layer is higher than a second total area occupancy proportion of the fiber-shaped conductive members, the dielectric layer, and the conductor layer in the central region.

9. The capacitor according to claim 1, wherein in the section in the in-plane direction of the substrate, an outer peripheral region on at least one of a first side and a second side with a central region corresponding to the width W₁ sandwiched therebetween includes a part where a first total area occupancy proportion of the fiber-shaped conductive members, the dielectric layer, and the conductor layer is higher than a second total area occupancy proportion of the fiber-shaped conductive members, the dielectric layer, and the conductor layer in the central region.

10. The capacitor according to claim 1, wherein
each of the fiber-shaped conductive members has a maximum height Hₘₐₓ in a central region corresponding to the width W₁, and W₂>Hₘₐₓ.

11. The capacitor according to claim 1, wherein the dielectric layer has a thickness of 10 nm or more.

12. The capacitor according to claim 1, wherein the plurality of fiber-shaped conductive members have an average number density of 10⁸ fibers/cm² or more.

13. The capacitor according to claim 1, wherein the plurality of fiber-shaped conductive members have an average length of 50 μm or more.

14. The capacitor according to claim 1, wherein the plurality of fiber-shaped conductive members are carbon nanotubes.

15. The capacitor according to claim 1, wherein the plurality of fiber-shaped conductive members are directly joined to the substrate.

16. The capacitor according to claim 1, wherein interior angle of a side of the composite bulk member connecting the side thereof opposite to the substrate to the side thereof proximal to the substrate is less than 90 degrees.

17. The capacitor according to claim 2, wherein W₂>Hₘₐₓ.

18. The capacitor according to claim 17, wherein W₂ is four time or move of the Hₘₐₓ.

19. The capacitor according to claim 1, wherein a strength of the plurality of fiber-shaped conductive members is 5 MPa/(nm)² to 150 Gpa/(nm)².
